(19) United States
(12) Patent Application Publication
(10) Pub. No.: US 2012/0131407 A1
(43) Pub. Date: May 24, 2012

(54) LAYER-AWARE FORWARD ERROR CORRECTION ENCODING AND DECODING METHOD, ENCODING APPARATUS, DECODING APPARATUS, AND SYSTEM THEREOF

(75) Inventors: Hsin-Ta Chiao, Nantou County (TW); Hung-Min Sun, Hsinchu City (TW); Shih-Ying Chang, Nantou County (TW)

(73) Assignee: INDUSTRIAL TECHNOLOGY RESEARCH INSTITUTE, Hsinchu (TW)

(21) Appl. No.: 13/078,932

(22) Filed: Apr. 2, 2011

(30) Foreign Application Priority Data
Nov. 18, 2010 (TW) 99139737

(51) Int. Cl. H03M 13/00; G06F 11/10

(52) U.S. Cl. 714/751; 714/E11.044

(57) ABSTRACT

A layer-aware Forward Error Correction (FEC) encoding and decoding method for encoding and decoding an information content, an encoding apparatus, a decoding apparatus, and a system thereof are provided, wherein the information content has a plurality of layer source symbol sets. In the encoding method, source symbols of each layer are encoded into encoding symbols corresponding to the layer by using an FEC encoder. In addition, final encoding symbols of an upper layer are generated by aggregating encoding symbols of both the upper layer and a lower layer. Thereby, the layer-aware FEC encoding method can maintain the encoding/decoding dependency between different layers of data without increasing the complexity of the encoding/decoding operations.

### CROSS-REFERENCE TO RELATED APPLICATION

This application claims the priority benefit of Taiwan application serial no. 99139737, filed on Nov. 18, 2010. The entirety of the above-mentioned patent application is hereby incorporated by reference herein and made a part of this specification.

### TECHNICAL FIELD

The disclosure relates to a layer-aware Forward Error Correction (FEC) encoding and decoding method, a layer-aware FEC encoding apparatus, a layer-aware FEC decoding apparatus, and a layer-aware FEC encoding/decoding system.

### BACKGROUND

The Scalable Video Coding (SVC) technology has been broadly applied to video transmission. SVC is to partition the data of a video into different layers according to the significance or dependency thereof so as to efficiently transmit the video data to receivers of different capabilities. For example, a video data is usually divided into base layer data and enhancement layer data. A terminal device having lower capability can receive the base layer data and render the video data with lower quality, while a terminal device having higher capability can receive both the base layer data and the enhancement layer data and render the video data with higher quality. Accordingly, the SVC technology can effectively reduce the network transmission bandwidth or the power consumption of terminal devices. Because SVC allows a video data to be received and presented at terminal devices with different capabilities by encoding the video data only once, the designs of servers or head ends for supporting terminal devices having different capabilities can be simplified.

Regarding the application of SVC, an inter-layer prediction mode can be turned on in order to increase the video compression ratio. However, in the inter-layer prediction mode, the enhancement layer data can be decoded only after the base layer data is received. Namely, the base layer data is relatively more significant to the decidability of an SVC video.

Generally speaking, there is usually data loss in data transmission due to the characteristics of the transmission medium. Thus, when data is transmitted over medium that may easily cause data loss (for example, a wireless network), the data is usually encoded through the Forward Error Correction (FEC) technique. One advantage of the FEC technique is that a receiver can reconstruct the source data by receiving some additional FEC data without data retransmission. To be specific, through the FEC technique, data composed of K source symbols (SS) can be encoded into many, or even an unlimited number of, encoding symbols (ES). The original data can be reconstructed when any K(1+ε) of the encoding symbols are received, wherein c indicates the overhead. Thereby, no data retransmission is required if the FEC technique is adopted.

The FEC technique can be implemented and cooperated with the SVC technique by individually encoding and decoding the data of each layer. Herein even though data loss is prevented on each layer by encoding the data through the FEC technique, the problem of data dependency cannot be resolved. Namely, if the complete base layer data cannot be received or restored after it is transmitted, the corresponding video cannot be successfully decoded and rendered.

In order to resolve the problem of data dependency, a layer-aware FEC infrastructure is developed such that data encodings on different layers are possible to be dependent on each other. Accordingly, the receiver can construct the base layer data by using the enhancement layer data in the case that the complete base layer data cannot be restored only using the encoding symbols in the base layer.

FIG. 1A and FIG. 1B are the diagrams illustrating the conventional layer-aware FEC encoding and decoding techniques. Herein the base layer data and the enhancement layer data of video data are respectively divided into a plurality of source symbols before they are transmitted, the source symbols are encoded into encoding symbols by an FEC encoder in the transmitter, and the encoding symbols are restored into the original source symbols by an FEC decoder in the receiver.

Referring to FIG. 1A, when the transmitter is about to encode the video data composed of the base layer data and the enhancement layer data, the FEC encoder 102A encodes a base layer source symbol set SS_{BL} to generate a base layer encoding symbol set ES_{BL}, and the FEC encoder 104A encodes the base layer source symbol set SS_{BL} and an enhancement layer source symbol set SS_{EL} to generate an enhancement layer encoding symbol set ES_{EL}. After that, the transmitter transmits the base layer encoding symbol set ES_{BL} and the enhancement layer encoding symbol set ES_{EL} to the receiver via a transmission channel.

Referring to FIG. 1B, when the receiver is about to decode the received base layer encoding symbol set ES′_{BL} and enhancement layer encoding symbol set ES′_{EL}, the FEC decoder 102B corresponding to the FEC encoder 102A decodes the base layer encoding symbol set ES′_{BL} to try to restore the base layer source symbol set SS_{BL}, and the FEC decoder 104B corresponding to the FEC encoder 104A decodes the base layer encoding symbol set ES′_{BL} and the enhancement layer encoding symbol set ES′_{EL} to try to restore both the base layer source symbol set SS_{BL} and the enhancement layer source symbol set SS_{EL}. Herein because transmission errors may occur, the base layer encoding symbol set ES′_{BL} received by the receiver is possible to be smaller than the base layer encoding symbol set ES_{BL} transmitted by the transmitter. Namely, the base layer encoding symbol set ES′_{BL} received by the receiver is a subset of the base layer encoding symbol set ES_{BL}.

Referring to the decoding operation illustrated in FIG. 1B, when the enhancement layer data is decoded, the input data includes the base layer encoding symbol set ES′_{BL} and the enhancement layer encoding symbol set ES′_{EL}, and when the base layer encoding symbol set ES′_{BL} and the enhancement layer encoding symbol set ES′_{EL} can be correctly decoded, the restored data includes the base layer source symbol set SS_{BL} and the enhancement layer source symbol set SS_{EL}. Thus, through the layer-aware FEC technique, a lower-layer data (i.e., the base layer data) is reconstructed with the assistance of an upper-layer data (i.e., the enhancement layer data).

The problem of data dependency can be resolved by applying the layer-aware FEC infrastructure described above in SVC. However, because the encoding and decoding of upper-layer data is related to lower-layer data, the operation complexity increases along with the increase of the number of layers.

In the FEC infrastructure with independent encoding for each layer, the order of the base layer data is k₀, and the order of the enhancement layer data is k₁. However, in the layer-aware FEC infrastructure, the order of the base layer data is k₀, while the order of the enhancement layer data is (k₀+k₁). For example, the encoding complexity of a matrix having an order k is about O(k²), and the decoding complexity thereof is about O(k³). Namely, the encoding/decoding complexity of each layer is not related only to the number of input symbols of the current layer but also to the numbers of input symbols of the current layer and all the lower layers. In particular, the encoding/decoding complexity, and accordingly the time for encoding/decoding data, both increase for a higher layer. For example, the decoding complexity of an n^{th} layer is related to (k₀+k₁+ . . . +kₙ). Thus, the encoding/decoding of higher-layer data in the layer-aware FEC infrastructure is more complicated and inefficient than that in the FEC infrastructure with independent encoding for each layer.

In addition, referring to the encoding/decoding procedures illustrated in FIG. 1A and FIG. 1B, the decoding of the enhancement layer data requires the encoding symbol sets of the base layer data and the enhancement layer data instead of simply the encoding symbols output by the FEC encoder on the enhancement layer. Thus, when the source symbols of the base layer data and the enhancement layer data are about to be encoded by using different FEC encoders, unfortunately the layer-aware FEC infrastructure may not work properly without appropriate modification.

Thereby, how to maintain the encoding/decoding dependency of different layers without increasing the complexity of the encoding/decoding operations has become one of the major subjects in the industry.

### SUMMARY

The disclosure is directed to a layer-aware Forward Error Correction (FEC) encoding and decoding method, wherein the encoding/decoding dependency between different layers of data of an information content is maintained without increasing the complexity of the encoding/decoding operations.

The disclosure is also directed to a layer-aware FEC encoder and a layer-aware FEC decoder, wherein the encoding/decoding dependency between different layers of data of an information content is maintained without increasing the complexity of the encoding/decoding operations.

The disclosure is further directed to layer-aware FEC encoding/decoding system, wherein the encoding/decoding dependency between different layers of data of an information content is maintained without increasing the complexity of the encoding/decoding operations.

The disclosure provides an exemplary embodiment of a layer-aware FEC encoding method for encoding an information content, wherein the information content has a plurality of layer source symbol sets (i.e., the source symbol sets from different layers), the layer source symbol sets include at least a first layer source symbol set and a second layer source symbol set, and the first layer source symbol set and the second layer source symbol set respectively have a plurality of source symbols. The layer-aware FEC encoding method includes encoding the source symbols of the first layer source symbol set by using a first FEC encoder to generate encoding symbols of a first layer encoding symbol set and encoding the source symbols of the second layer source symbol set by using a second FEC encoder to generate encoding symbols of a second layer encoding symbol set. The layer-aware FEC encoding method also includes serving the encoding symbols of the first layer encoding symbol set as encoding symbols of a first layer final encoding symbol set corresponding to the first layer source symbol set and executing an aggregation operation on the encoding symbols of the second layer encoding symbol set according to the encoding symbols of the first layer encoding symbol set to generate encoding symbols of a second layer final encoding symbol set corresponding to the second layer source symbol set.

The disclosure provides an exemplary embodiment of layer-aware FEC decoding method for decoding a plurality of final layer encoding symbol sets corresponding to an information content, wherein the final layer encoding symbol sets include at least a first layer final encoding symbol set and a second layer final encoding symbol set, and the first layer final encoding symbol set and the second layer final encoding symbol set respectively have a plurality of encoding symbols. The layer-aware FEC decoding method includes serving the first layer final encoding symbol set as a first layer encoding symbol set and executing a deaggregation operation on the encoding symbols of the second layer final encoding symbol set according to the encoding symbols of the first layer encoding symbol set to generate a second layer encoding symbol set and a non-deaggregatable encoding symbol set. The layer-aware FEC decoding method also includes generating a first layer source symbol set and a second layer source symbol set according to the first layer encoding symbol set, the second layer encoding symbol set, and the non-deaggregatable encoding symbol set by using a feedback loop FEC decoder.

The disclosure provides an exemplary embodiment of layer-aware FEC encoding apparatus for encoding an information content, wherein the information content has a plurality of layer source symbol sets, the layer source symbol sets include at least a first layer source symbol set and a second layer source symbol set, and the first layer source symbol set and the second layer source symbol set respectively have a plurality of source symbols. The layer-aware FEC encoder includes an encoding control module, a first FEC encoder, a second FEC encoder, and a symbol aggregator. The encoding control module receives the layer source symbol sets. The first FEC encoder encodes the source symbols of the first layer source symbol set to generate encoding symbols of a first layer encoding symbol set. The encoding control module serves the encoding symbols of the first layer encoding symbol set generated by the first FEC encoder as encoding symbols of a first layer final encoding symbol set corresponding to the first layer source symbol set. The second FEC encoder encodes the source symbols of the second layer source symbol set to output encoding symbols of a second layer encoding symbol set. The symbol aggregator executes an aggregation operation on the encoding symbols of the second layer encoding symbol set according to the encoding symbols of the first layer encoding symbol set to generate encoding symbols of a second layer final encoding symbol set corresponding to the second layer source symbol set. The encoding control module further outputs the encoding symbols of the first layer final encoding symbol set and the encoding symbols of the second layer final encoding symbol set.

The disclosure provides an exemplary embodiment of layer-aware FEC decoding apparatus for decoding a plurality of final layer encoding symbol sets corresponding to an information content, wherein the final layer encoding symbol sets include at least a first layer final encoding symbol set and a second layer final encoding symbol set, and the first layer final encoding symbol set and the second layer final encoding symbol set respectively include a plurality of encoding symbols. The layer-aware FEC decoding apparatus includes a decoding control module, a symbol deaggregator, and a feedback loop FEC decoder. The decoding control module serves the first layer final encoding symbol set as a first layer encoding symbol set. The symbol deaggregator executes a deaggregation operation on the encoding symbols of the second layer final encoding symbol set according to the encoding symbols of the first layer encoding symbol set to generate a second layer encoding symbol set and a non-deaggregatable encoding symbol set. The feedback loop FEC decoder generates a first layer source symbol set and a second layer source symbol set according to the first layer encoding symbol set, the second layer encoding symbol set, and the non-deaggregatable encoding symbol set. The decoding control module further outputs the first layer source symbol set and the second layer source symbol set.

The disclosure provides an exemplary embodiment of layer-aware FEC encoding/decoding system including a controller, a first FEC encoder, a second FEC encoder, a symbol aggregator, a symbol deaggregator, and a feedback loop FEC decoder. The controller includes an encoding control module and a decoding control module. The encoding control module receives a plurality of layer source symbol sets of a first information content, wherein the layer source symbol sets of the first information content include at least a first layer source symbol set and a second layer source symbol set of the first information content, and the first layer source symbol set and the second layer source symbol set of the first information content respectively have a plurality of source symbols. The decoding control module receives a plurality of final layer encoding symbol sets corresponding to a second information content, wherein the final layer encoding symbol sets of the second information content include at least a first layer final encoding symbol set and a second layer final encoding symbol set of the second information content, the first layer final encoding symbol set and the second layer final encoding symbol set of the second information content respectively have a plurality of encoding symbols, and the decoding control module serves the first layer final encoding symbol set of the second information content as a first layer encoding symbol set of the second information content. The first FEC encoder encodes the source symbols of the first layer source symbol set of the first information content to generate encoding symbols of a first layer encoding symbol set of the first information content, and the encoding control module serves the encoding symbols of the first layer encoding symbol set of the first information content as encoding symbols of a first layer final encoding symbol set of the first information content. The second FEC encoder encodes the source symbols of the second layer source symbol set of the first information content to generate encoding symbols of a second layer encoding symbol set of the first information content, wherein the second layer encoding symbol set of the first information content has a plurality of encoding symbols. The symbol aggregator executes an aggregation operation on the encoding symbols of the second layer encoding symbol set of the first information content according to the encoding symbols of the first layer encoding symbol set of the first information content to generate encoding symbols of a second layer final encoding symbol set of the first information content. The symbol deaggregator executes a deaggregation operation on the encoding symbols of the second layer final encoding symbol set of the second information content according to the encoding symbols of the first layer encoding symbol set of the second information content to generate a second layer encoding symbol set and a non-deaggregatable encoding symbol set of the second information content. The feedback loop FEC decoder generates a first layer source symbol set and a second layer source symbol set of the second information content according to the first layer encoding symbol set, the second layer encoding symbol set, and the non-deaggregatable encoding symbol set of the second information content. Herein the controller further outputs the encoding symbols of the first layer final encoding symbol set and the second layer final encoding symbol set of the first information content and outputs the source symbols of the first layer source symbol set and the second layer source symbol set of the second information content.

Thereby, exemplary embodiments of the disclosure provide a layer-aware FEC encoding and decoding method, a layer-aware FEC encoder, a layer-aware FEC decoder, and a layer-aware FEC encoding/decoding system, wherein the encoding/decoding dependency between different layers of data of an information content is maintained without increasing the complexity of the encoding/decoding operations.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments, and together with the description, serve to explain the principles of the disclosure.

FIG. 1A and FIG. 1B are diagrams illustrating the conventional layer-aware Forward Error Correction (FEC) encoding and decoding techniques.

FIG. 2 illustrates a layer-aware FEC encoder according to a first exemplary embodiment of the disclosure.

FIG. 3 is a diagram illustrating an encoding operation of the layer-aware FEC encoder in FIG. 2.

FIG. 4 is a flowchart of an aggregation operation according to the first exemplary embodiment of the disclosure.

FIG. 5 illustrates an implementation example of a symbol aggregator according to the first exemplary embodiment of the disclosure.

FIG. 6 illustrates an example of an aggregation operation according to the first exemplary embodiment of the disclosure.

FIG. 7 is a flowchart of a layer-aware FEC encoding method according to the first exemplary embodiment of the disclosure.

FIG. 8 illustrates a layer-aware FEC decoding apparatus according to a second exemplary embodiment of the disclosure.

FIG. 9 is a diagram illustrating a decoding operation of the layer-aware FEC decoding apparatus in FIG. 8.

FIG. 10 is a flowchart of a deaggregation operation according to the second exemplary embodiment of the disclosure.

FIG. 11 illustrates an implementation example of a symbol deaggregator according to the second exemplary embodiment of the disclosure.

FIG. 12 illustrates an example of a deaggregation operation according to the second exemplary embodiment of the disclosure.

FIG. 13 is a flowchart illustrating the operation of a feedback loop FEC decoder according to the second exemplary embodiment of the disclosure.

FIG. 14 is a diagram illustrating the operation of a feedback loop FEC decoder according to the second exemplary embodiment of the disclosure.

FIG. 15 and FIG. 16 illustrate implementation examples of a feedback FEC encoder and a feedback loop FEC decoder according to the second exemplary embodiment of the disclosure.

FIG. 17 is a block diagram of a layer-aware FEC encoding/decoding system according to a third exemplary embodiment of the disclosure.

FIG. 18 is a diagram illustrating an encoding operation according to a fourth exemplary embodiment of the disclosure.

FIG. 19 is a diagram illustrating a decoding operation according to a fifth exemplary embodiment of the disclosure.

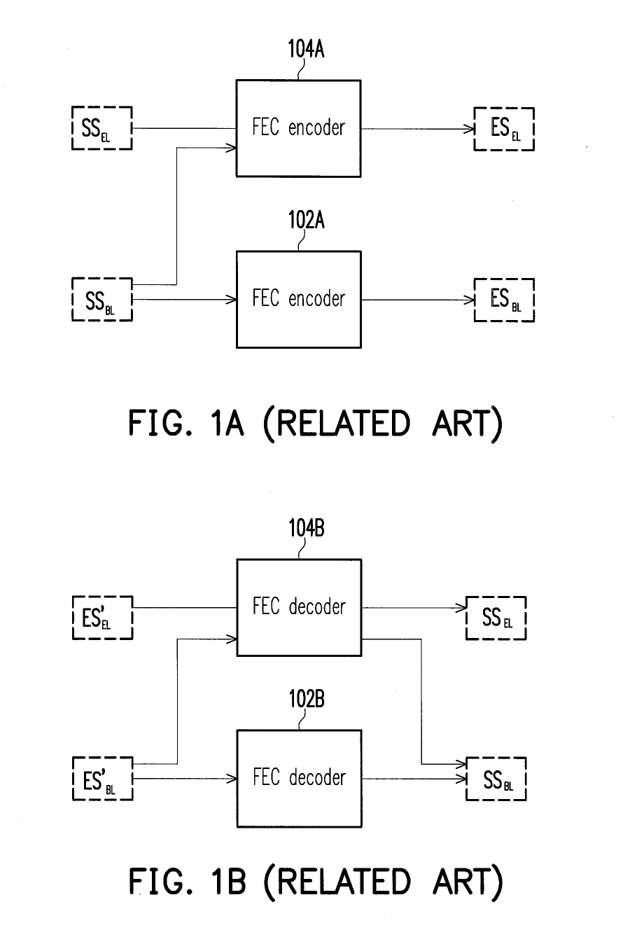

### DETAILED DESCRIPTION OF DISCLOSED EMBODIMENTS

### First Exemplary Embodiment

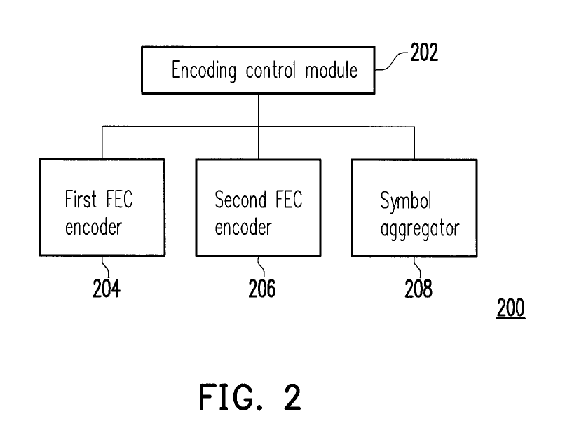

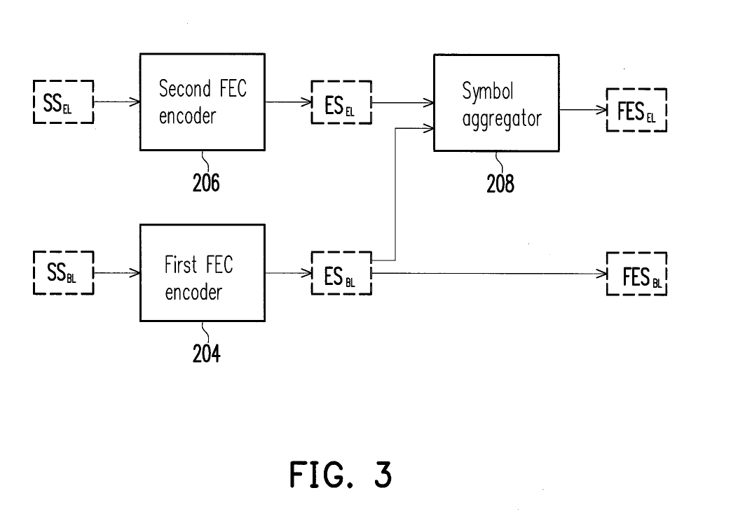

FIG. 2 illustrates a layer-aware Forward Error Correction (FEC) encoder according to the first exemplary embodiment of the disclosure, and FIG. 3 is a diagram illustrating an encoding operation of the layer-aware FEC encoder in FIG. 2.

Referring to FIG. 2 and FIG. 3, the layer-aware FEC encoding apparatus 200 includes an encoding control module 202, a first FEC encoder 204, a second FEC encoder 206, and a symbol aggregator 208.

The encoding control module 202 controls the operation of the entire layer-aware FEC encoding apparatus 200. To be specific, the encoding control module 202 controls the first FEC encoder 204, the second FEC encoder 206, and the symbol aggregator 208 to encode an information content to be transmitted by a transmitter (not shown) and output final encoding symbols corresponding to the information content. Then, the transmitter transmits the final encoding symbols corresponding to the information content to a receiver via a transmission channel (not shown). Herein the transmitter may be the transmitter of any wireless or wired communication device. For example, the layer-aware FEC encoding apparatus 200 may be integrated in the transmitter or connected to the transmitter through external connection. In addition, in the present exemplary embodiment, source coding is performed on the information content to be transmitted by the transmitter through an Scalable Video Coding (SVC) technique, and the information content is divided into data of a plurality of layers. For the convenience of description, the encoding operation is described only regarding data on a first layer (referred to as a base layer thereinafter) and data on a second layer (referred to as a enhancement layer thereinafter) of the information content. However, the disclosure is not limited thereto, and in another exemplary embodiment of the disclosure, the information content may contain data of multiple enhancement layers corresponding to receivers of different capabilities (for example, video rendering capabilities or transmission capabilities).

The first FEC encoder 204 is coupled to the encoding control module 202. The first FEC encoder 204 encodes the base layer data (referred to as a base layer source symbol set SS_{BL} thereinafter) of the information content to generate encoding symbols (i.e., a base layer encoding symbol set ES_{BL}) corresponding to the base layer source symbol set SS_{BL}. In the present exemplary embodiment, the encoding control module 202 outputs the base layer encoding symbol set ES_{BL} generated by the first FEC encoder 204 as a base layer final encoding symbol set FES_{BL} corresponding to the base layer source symbol set SS_{BL}.

The second FEC encoder 206 is coupled to the encoding control module 202. The second FEC encoder 206 encodes the enhancement layer data (referred to as an enhancement layer source symbol set SS_{EL} thereinafter) of the information content to generate encoding symbols (i.e., an enhancement layer encoding symbol set ES_{EL}) corresponding to the enhancement layer source symbol set SS_{EL}.

In the present exemplary embodiment, the first FEC encoder 204 and the second FEC encoder 206 may be implemented with an existing FEC algorithm, such as the Reed-Solomon (RS) coding or fountain coding. Besides, the first FEC encoder 204 and the second FEC encoder 206 may adopt the same FEC algorithm or different FEC algorithms as long as the symbol size of encoding symbols generated by the first FEC encoder 204 is the same as the symbol size of encoding symbols generated by the second FEC encoder 206. For example, in the present exemplary embodiment, the first FEC encoder 204 and the second FEC encoder 206 are both implemented as Luby transform (LT) encoders. However, in another exemplary embodiment of the disclosure, the first FEC encoder 204 is an LT encoder, while the second FEC encoder 206 is a Raptor encoder.

The symbol aggregator 208 is coupled to the encoding control module 202 and is configured to execute an aggregation operation on the base layer encoding symbol set ES_{BL} generated by the first FEC encoder 204 and the enhancement layer encoding symbol set ES_{EL} generated by the second FEC encoder 206 to generate an enhancement layer final encoding symbol set FES_{EL} corresponding to the enhancement layer source symbol set SS_{EL}. Namely, the encoding control module 202 outputs the encoding symbol set generated by the symbol aggregator 208 as the enhancement layer final encoding symbol set FES_{EL} corresponding to the enhancement layer source symbol set SS_{EL}.

In the aggregation operation, the symbol aggregator 208 divides the encoding symbols of the enhancement layer encoding symbol set ES_{EL} into a first encoding symbol group and a second encoding symbol group, wherein the encoding symbols in the first encoding symbol group are directly served as a portion of the enhancement layer final encoding symbol set FES_{EL}. Besides, the symbol aggregator 208 executes the aggregation operation on the encoding symbols in the second encoding symbol group according to the encoding symbols of the base layer encoding symbol set ES_{BL} to generate aggregate encoding symbol, wherein the aggregate encoding symbols are served as another portion of the enhancement layer final encoding symbol set FES_{EL}. Herein the aggregate encoding symbols form an aggregate encoding symbol set.

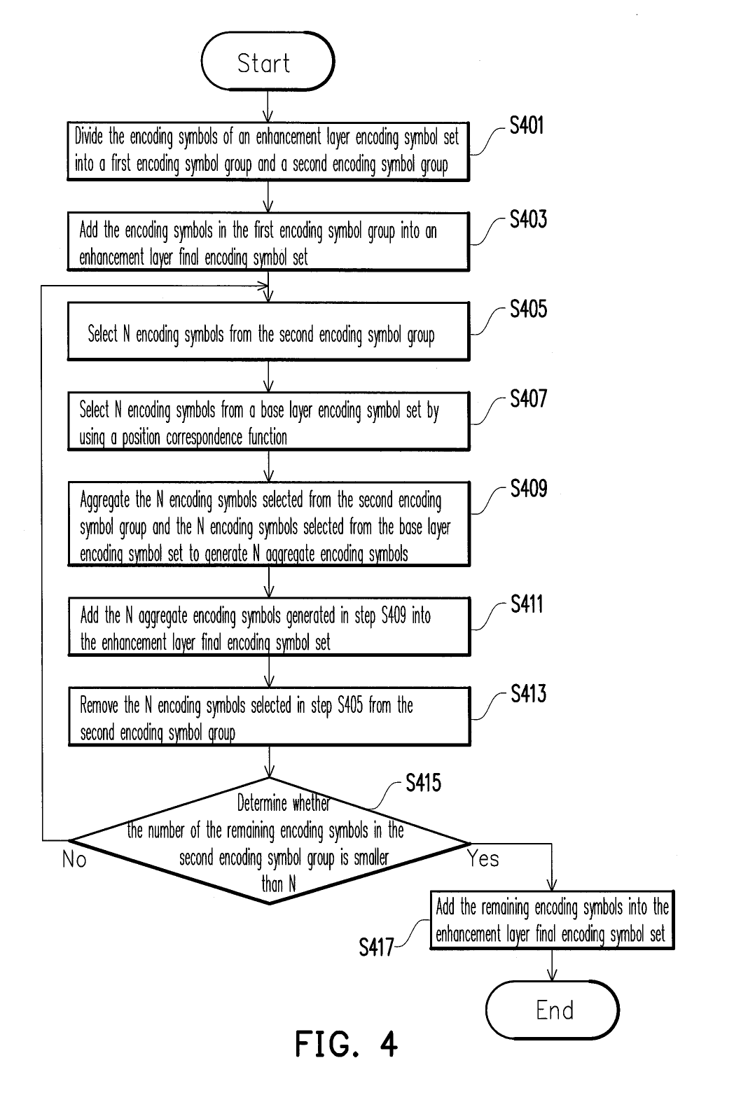

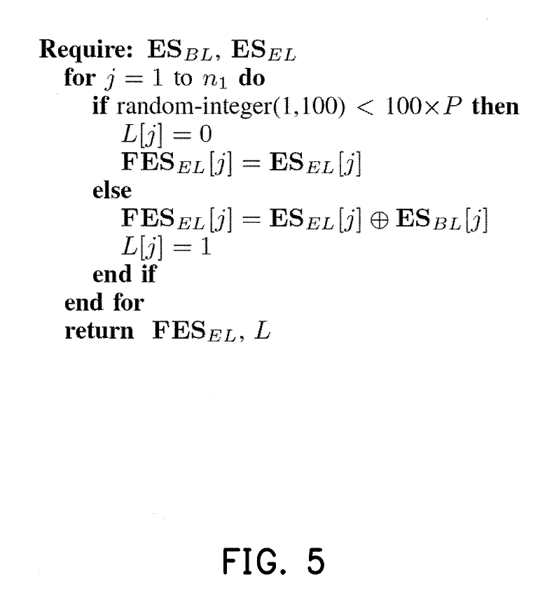

FIG. 4 is a flowchart of an aggregation operation according to the first exemplary embodiment of the disclosure, and FIG. 5 illustrates an implementation example of a symbol aggregator according to the first exemplary embodiment of the disclosure. It should be understood that the structure illustrated in FIG. 5 is only an example of symbol aggregator but not intended to limit the scope of the disclosure.

Referring to FIG. 4 and FIG. 5, in step S401, the symbol aggregator 208 divides the encoding symbols of the enhancement layer encoding symbol set ES_{EL} into a first encoding symbol group and a second encoding symbol group.

In the present exemplary embodiment, the symbol aggregator 208 determines the encoding symbols of the enhancement layer encoding symbol set ES_{EL} that belong to the first encoding symbol group according to a probability value P. Herein the probability value P is pre-determined according to the transmission environment between a transmitter and a receiver. For example, if the probability value P is set to 80%, it means 80% of the encoding symbols of the enhancement layer encoding symbol set ES_{EL} are grouped into the first encoding symbol group, while 20% of the encoding symbols of the enhancement layer encoding symbol set ES_{EL} are grouped into the second encoding symbol group.

The probability value P determines whether the base layer data and the enhancement layer data can be successfully restored. For example, when it is assumed that n₀ and n₁ respectively represent the number of encoding symbols of the base layer encoding symbol set ES_{BL} and the number of encoding symbols of the enhancement layer encoding symbol set ES_{EL}, and k₀ and k₁ respectively represent the number of source symbols of the base layer source symbol set SS_{BL} and the number of source symbols of the enhancement layer source symbol set SS_{EL}, the effective encoding symbol number of the base layer data is (n₀+(n₁×(1−P))) at most and the effective encoding symbol number of the enhancement layer data is (n₁×P+(n₁×(1−P))) at most. To be specific, the smaller the probability value P is, the more protection the base layer data can be done. However, preferably, (n₁×(1−P)) aggregate encoding symbols can all be separated (i.e., deaggregated). If both the base layer data and the enhancement layer data are expected to be restored, the probability value P should satisfy:

(k₁−n₁×p₀×p₁)/n₁×p₁(1−p₀))≦P≦1−(k₀−n₀×p₀)/n₁×p₁×(1−p₀)

In foregoing expression, p₀ and p₁ respectively represent the ratio of the received encoding symbols in the base layer encoding symbol set ES_{BL} and the ratio of the received encoding symbols in the enhancement layer encoding symbol set ES_{EL} in a transmission environment. Accordingly, the upper and lower limits of the probability value P can be obtained through foregoing expression. In other words, it is possible to reconstruct the base layer data and the enhancement layer data if the probability value P is set to be between the upper and lower limits.

In the present exemplary embodiment, the symbol aggregator 208 randomly groups the encoding symbols of the enhancement layer encoding symbol set ES_{EL} according to the probability value P (as shown in FIG. 5). However, in another exemplary embodiment of the disclosure, the symbol aggregator 208 may also group the encoding symbols of the enhancement layer encoding symbol set ES_{EL} through a designated mechanism. For example, when the probability value P is set to 50%, the symbol aggregator 208 groups encoding symbols at an odder number index into the first encoding symbol group and groups encoding symbols at an even number index into the second encoding symbol group.

In step S403, the symbol aggregator 208 adds the encoding symbols in the first encoding symbol group into the enhancement layer final encoding symbol set FES_{EL}.

In step S405, the symbol aggregator 208 selects N encoding symbols from the second encoding symbol group. In the present exemplary embodiment, the symbol aggregator 208 performs the aggregation operation in unit of N encoding symbols, wherein N is a natural number.

In step S407, the symbol aggregator 208 selects N encoding symbols from the base layer encoding symbol set ES_{BL} by using a position correspondence function. In the position correspondence function, the encoding symbols of the base layer encoding symbol set ES_{BL} and the encoding symbols of the enhancement layer encoding symbol set ES_{EL} are respectively corresponding to each other. Thereby, the symbol aggregator 208 selects the N encoding symbols from the base layer encoding symbol set ES_{BL} according to the positions of the N encoding symbols selected from the second encoding symbol group. However, the position correspondence function is not limited herein, and which may also be implemented by taking other position correspondence patterns.

In step S409, the symbol aggregator 208 aggregates the N encoding symbols selected from the second encoding symbol group and the N encoding symbols selected from the base layer encoding symbol set ES_{BL} to generate N aggregate encoding symbols. For example, the symbol aggregator 208 performs an XOR operation on the N encoding symbols selected from the second encoding symbol group with the N encoding symbols selected from the base layer encoding symbol set ES_{BL}.

Thereafter, in step S411, the symbol aggregator 208 adds the N aggregate encoding symbols generated in step S409 into the enhancement layer final encoding symbol set FES_{EL}. To be specific, in step S411, the symbol aggregator 208 adds the aggregate encoding symbols into an aggregate encoding symbol set, wherein these aggregate encoding symbols added into the aggregate encoding symbol set are all merged into the enhancement layer final encoding symbol set FES_{EL} after the aggregation operation is performed. For example, as shown in FIG. 5, whether the encoding symbols are aggregated is recorded with a variable L[j], wherein j represents the position of an encoding symbol. If the j^{th} encoding symbol has been aggregated, the value of L[j] is 1. Contrarily, if the j^{th} encoding symbol is not aggregated, the value of L[j] is 0. Accordingly, the aggregate encoding symbols in the enhancement layer final encoding symbol set FES_{EL} can be distinguished according to the value of the variable L[j].

In step S413, the symbol aggregator 208 removes the N encoding symbols selected in step S405 from the second encoding symbol group, and in step S415, the symbol aggregator 208 determines whether the number of other encoding symbols (i.e., the remaining encoding symbols) in the second encoding symbol group is smaller than N.

If the number of the remaining encoding symbols in the second encoding symbol group is smaller than N, in step S417, the symbol aggregator 208 adds the remaining encoding symbols into the enhancement layer final encoding symbol set FES_{EL}. Besides, if the number of the remaining encoding symbols in the second encoding symbol group is not smaller than N, steps S405, S407, S409, S411, S413, and S415 are repeated.

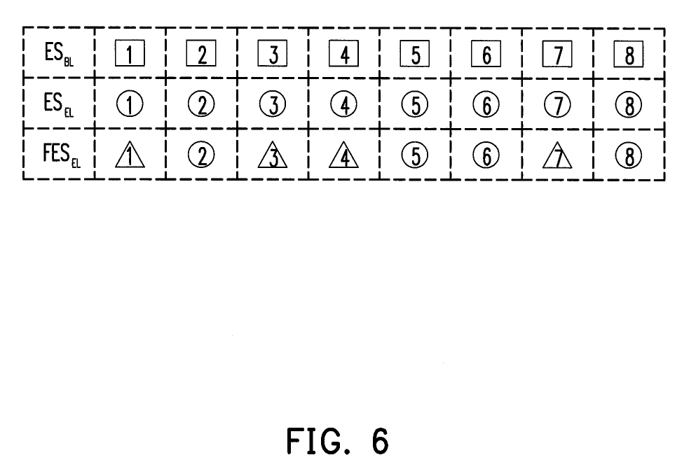

FIG. 6 illustrates an example of an aggregation operation according to the first exemplary embodiment of the disclosure.

Referring to FIG. 6, it is assumed that the base layer encoding symbol set ES_{BL} generated by the first FEC encoder 204 contains 8 encoding symbols (i.e., the 8 encoding symbols denoted with squares) and the enhancement layer encoding symbol set ES_{EL} generated by the second FEC encoder 206 contains 8 encoding symbols (i.e., the 8 encoding symbols denoted with circles). If the symbol aggregator 208 randomly groups the 2^{nd}, 5^{th}, 6^{th}, and 8^{th} encoding symbols of the enhancement layer encoding symbol set ES_{EL} into the first encoding symbol group and the 1^{st}, 3^{rd}, 4^{th}, and 7^{th} encoding symbols of the enhancement layer encoding symbol set ES_{EL} into the second encoding symbol group, the symbol aggregator 208 respectively executes the XOR operation on the 1^{st}, 3^{rd}, 4^{th}, and 7^{th} encoding symbols of the enhancement layer encoding symbol set ES_{EL} with the 1^{st}, 3^{rd}, 4^{th}, and 7^{th} encoding symbols of the base layer encoding symbol set ES_{BL} to generate the aggregate encoding symbols (i.e., the encoding symbols denoted with triangles). After that, the aggregate encoding symbol replace the 1^{st}, 3^{rd}, 4^{th}, and 7^{th} encoding symbols of the enhancement layer encoding symbol set ES_{EL} and form the enhancement layer final encoding symbol set FES_{EL} with the encoding symbols in the first encoding symbol group. Namely, in the present exemplary embodiment, the aggregate encoding symbols replace the encoding symbols of the enhancement layer encoding symbol set ES_{EL} so that the coding rate of the enhancement layer remains the same without performing any additional redundancy encoding.

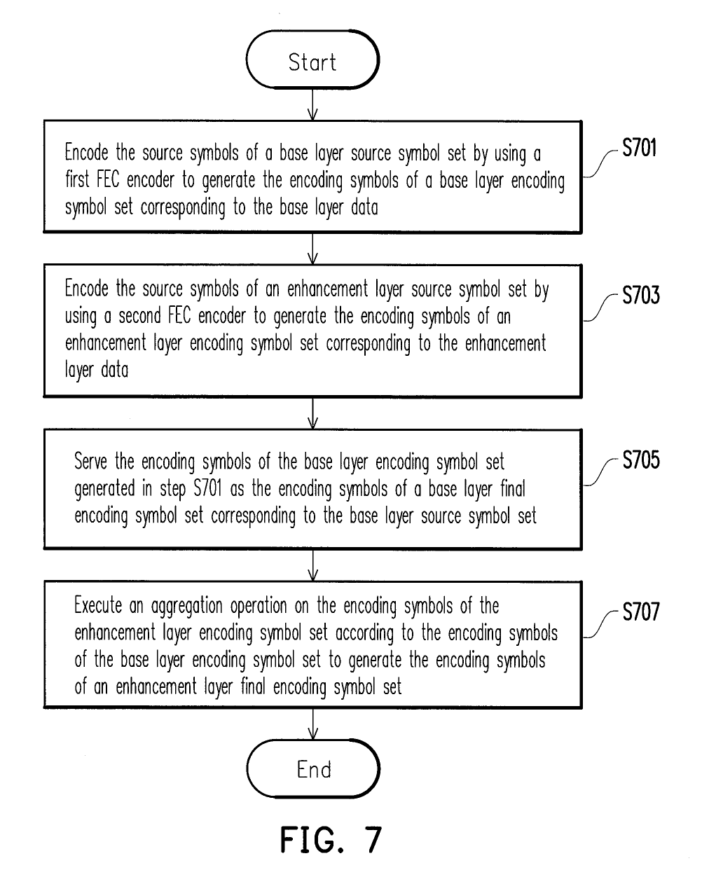

FIG. 7 is a flowchart of a layer-aware FEC encoding method according to the first exemplary embodiment of the disclosure.

Referring to FIG. 7, in step S701, the source symbols of the base layer source symbol set SS_{BL} are encoded by the first FEC encoder 204 to generate the encoding symbols of the base layer encoding symbol set ES_{BL} corresponding to the base layer data, and in step S703, the source symbols of the enhancement layer source symbol set SS_{EL} are encoded by the second FEC encoder 206 to generate the encoding symbols of the enhancement layer encoding symbol set ES_{EL} corresponding to the enhancement layer data.

In step S705, the encoding symbols of the base layer encoding symbol set ES_{BL} generated in step S701 are served as the encoding symbols of the base layer final encoding symbol set FES_{BL} corresponding to the base layer source symbol set SS_{BL}.

In step S707, an aggregation operation is executed on the encoding symbols of the enhancement layer encoding symbol set ES_{EL} according to the encoding symbols of the base layer encoding symbol set ES_{BL} to generate the encoding symbols of the enhancement layer final encoding symbol set FES_{EL} corresponding to the enhancement layer source symbol set SS_{EL}. How the aggregation operation is executed has been described above in detail with reference to FIG. 4 therefore will not be described herein.

### Second Exemplary Embodiment

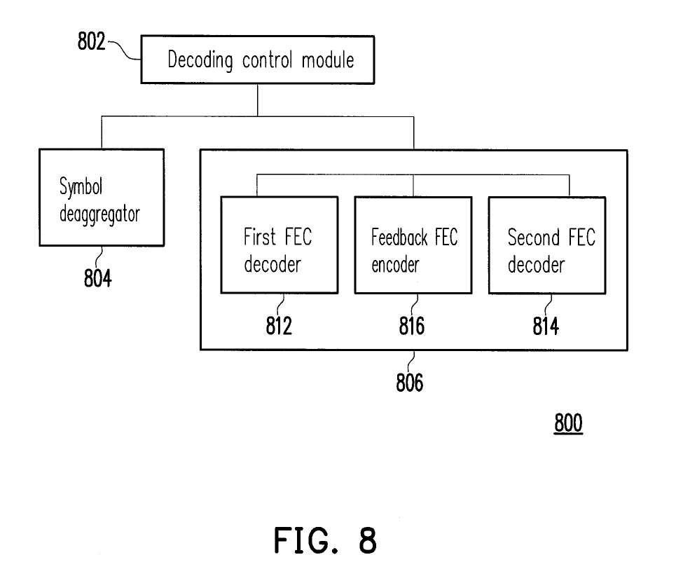

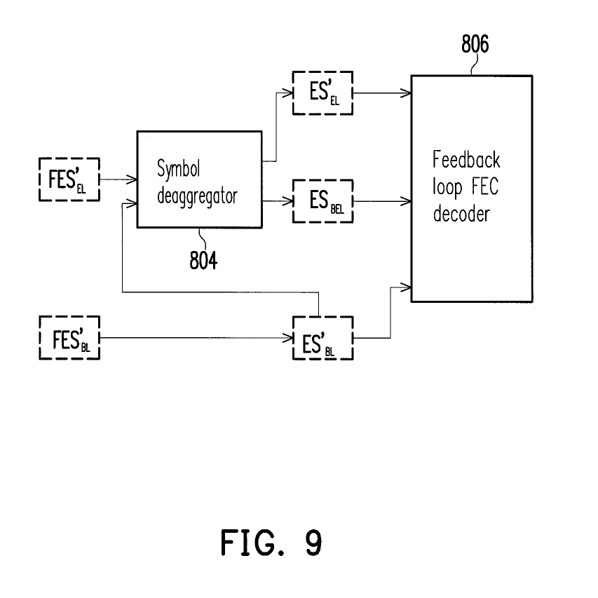

FIG. 8 illustrates a layer-aware FEC decoding apparatus according to the second exemplary embodiment of the disclosure, and FIG. 9 is a diagram illustrating a decoding operation of the layer-aware FEC decoding apparatus in FIG. 8, wherein the information content encoded by the layer-aware FEC encoding apparatus in the first exemplary embodiment is decoded.

Referring to FIG. 8 and FIG. 9, the layer-aware FEC decoding apparatus 800 includes a decoding control module 802, a symbol deaggregator 804, and a feedback loop FEC decoder 806.

The decoding control module 802 controls the operation of the entire layer-aware FEC decoding apparatus 800. To be specific, the decoding control module 802 controls the symbol deaggregator 804 and the feedback loop FEC decoder 806 to decode the final encoding symbols received by a receiver (not shown) to restore and output source symbols of the information content transmitted by a corresponding transmitter. Herein the receiver may be any receiver equipped with a wireless or a wired communication device. For example, the layer-aware FEC decoding apparatus 800 may be integrated in the receiver or connected to the receiver through an external connection. In addition, as described above, source coding is performed on the information content in the form of SVC encoding, and the final encoding symbols respectively belong to the data of a plurality of layers. For the convenience of description, herein the decoding operation is described only regarding a first layer (referred to as a base layer thereinafter) final encoding symbol set and a second layer (referred to as an enhancement layer thereinafter) final encoding symbol set of the information content. However, the disclosure is not limited thereto, and in another exemplary embodiment of the disclosure, the information content may contain data of multiple enhancement layers corresponding to receivers of different capabilities (for example, video rendering capabilities or transmission capabilities).

The symbol deaggregator 804 is coupled to the decoding control module 802 and configured to execute a deaggregation operation. For example, when the receiver receives encoding symbols of a base layer final encoding symbol set FES′_{BL} and encoding symbols of an enhancement layer final encoding symbol set FES′_{EL}, the decoding control module 802 serves the encoding symbols of the base layer final encoding symbol set FES′_{BL} as a base layer encoding symbol set ES′_{BL} corresponding to the base layer source symbol set SS_{BL}, and the symbol deaggregator 804 executes the deaggregation operation on the encoding symbols of the enhancement layer final encoding symbol set FES′_{EL} according to the encoding symbols of the base layer encoding symbol set ES′_{BL} to restore encoding symbol of an enhancement layer encoding symbol set ES′_{EL}.

In particular, because data loss may occur during the data transmission process, the encoding symbols of the base layer final encoding symbol set FES′_{BL} and the encoding symbols of the enhancement layer final encoding symbol set FES′_{EL} received by the receiver may be less than the encoding symbols of the base layer final encoding symbol set FES_{BL} and the encoding symbols of the enhancement layer final encoding symbol set FES_{EL} transmitted by the transmitter, respectively. In the first exemplary embodiment of the disclosure, the enhancement layer final encoding symbol set FES_{EL} is generated by the symbol aggregator 208 by aggregating the encoding symbols of the base layer encoding symbol set ES_{BL} and the encoding symbols of the enhancement layer encoding symbol set ES_{EL}. Thus, when the encoding symbols of the base layer final encoding symbol set FES′_{BL} and the encoding symbols of the enhancement layer final encoding symbol set FES′_{EL} received by the receiver are less than the encoding symbols of the base layer final encoding symbol set FES_{BL} and the encoding symbols of the enhancement layer final encoding symbol set FES_{EL} transmitted by the transmitter, some encoding symbols may not be restored through the deaggregation operation. In the second exemplary embodiment of the disclosure, the symbol deaggregator 804 further marks such non-restorable encoding symbols. Herein the set of these non-restorable encoding symbols is referred to as a non-deaggregatable encoding symbol set ES_{BEL}.

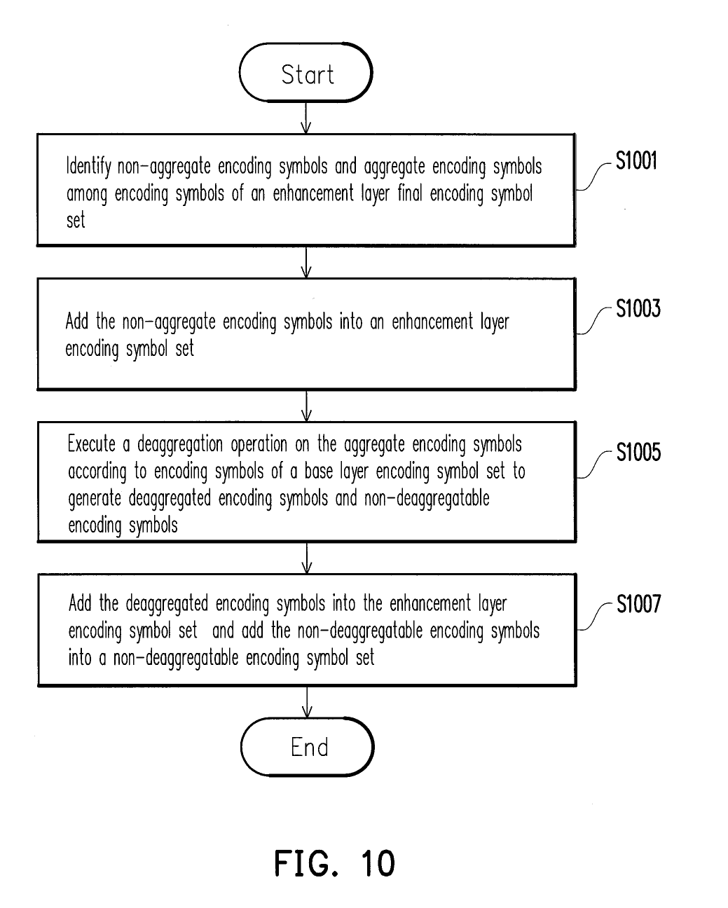

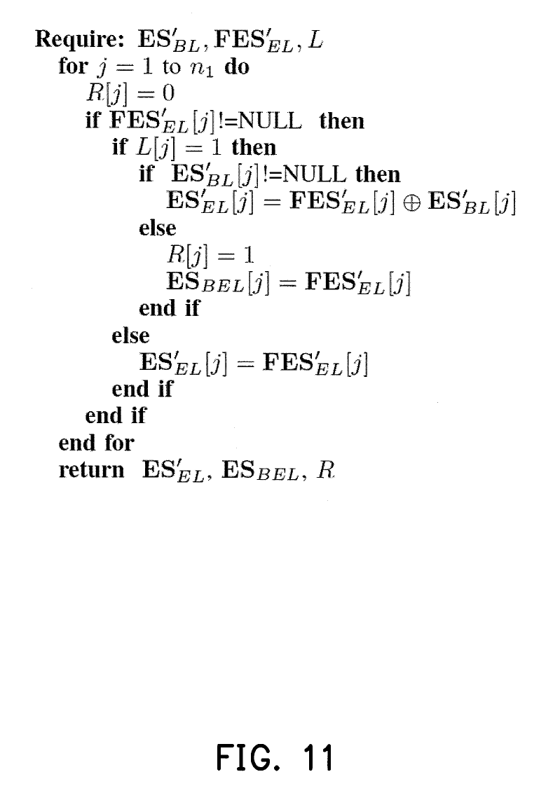

FIG. 10 is a flowchart of a deaggregation operation according to the second exemplary embodiment of the disclosure, and FIG. 11 illustrates an implementation example of a symbol deaggregator according to the second exemplary embodiment of the disclosure. It should be understood that the structure illustrated in FIG. 11 is only an example of symbol deaggregator but not intended to limit the scope of the disclosure.

Referring to FIG. 10 and FIG. 11, in step S1001, the symbol deaggregator 804 identifies non-aggregate encoding symbols and aggregate encoding symbols among the encoding symbols of the enhancement layer final encoding symbol set FES′_{EL}.

To be specific, as described above, the symbol aggregator 208 divides encoding symbols of the enhancement layer encoding symbol set ES_{EL} into a first encoding symbol group and a second encoding symbol group according to a probability value P. Herein the symbol deaggregator 804 identifies non-aggregate encoding symbols and aggregate encoding symbols among the encoding symbol of the enhancement layer final encoding symbol set FES′_{EL} according to the foregoing grouping result. For example, when the layer-aware FEC encoding apparatus 200 outputs the encoding symbols of the enhancement layer final encoding symbol set FES_{EL}, it also outputs a grouping table (the variable L[j] in FIG. 11), and the symbol deaggregator 804 identifies the non-aggregate encoding symbols and the aggregate encoding symbols among the encoding symbols of the enhancement layer final encoding symbol set FES′_{EL} according to the grouping table. Or, in another exemplary embodiment of the disclosure, both the layer-aware FEC encoding apparatus 200 and the layer-aware FEC decoding apparatus 800 generate a random number by using the same random number generator and the same seed, so that the symbol deaggregator 804 can reconstruct the grouping table according to the same random number generator and the same seed while deaggregating data during the decoding process for identifying the non-aggregate encoding symbols and the aggregate encoding symbols among the encoding symbols of the enhancement layer final encoding symbol set FES′_{EL}.

In step S1003, the symbol deaggregator 804 adds the non-aggregate encoding symbols into the enhancement layer encoding symbol set ES′_{EL}. To be specific, because the symbol aggregator 208 does not perform the aggregation operation on the non-aggregate encoding symbols of the enhancement layer final encoding symbol set FES′_{EL}, the non-aggregate encoding symbols are a portion of the encoding symbols of the enhancement layer encoding symbol set ES′_{EL}.

In step S1005, the symbol deaggregator 804 executes a deaggregation operation on the aggregate encoding symbols according to the encoding symbols of the base layer encoding symbol set ES′_{BL} to generate deaggregated encoding symbols and non-deaggregatable encoding symbols. In an example wherein the symbol aggregator 208 generates the aggregate encoding symbols through an XOR operation, the symbol deaggregator 804 restores the deaggregated encoding symbols also through an XOR operation.

In step S1007, the symbol deaggregator 804 adds the deaggregated encoding symbols into the enhancement layer encoding symbol set ES′_{EL} and adds the non-deaggregatable encoding symbols into the non-deaggregatable encoding symbol set ES_{BEL}. For example, as shown in FIG. 11, whether the encoding symbols of the enhancement layer final encoding symbol set FES′_{EL} are deaggregated is recorded with the variable R[j], wherein j represents the position of the encoding symbol. If the j^{th} encoding symbol cannot be deaggregated, the value of R[j] is 1. Otherwise, if the j^{th} encoding symbol can be deaggregated, the value of R[j] is 0. Thereby, the non-deaggregatable encoding symbol can be distinguished according to the value of the variable R[j].

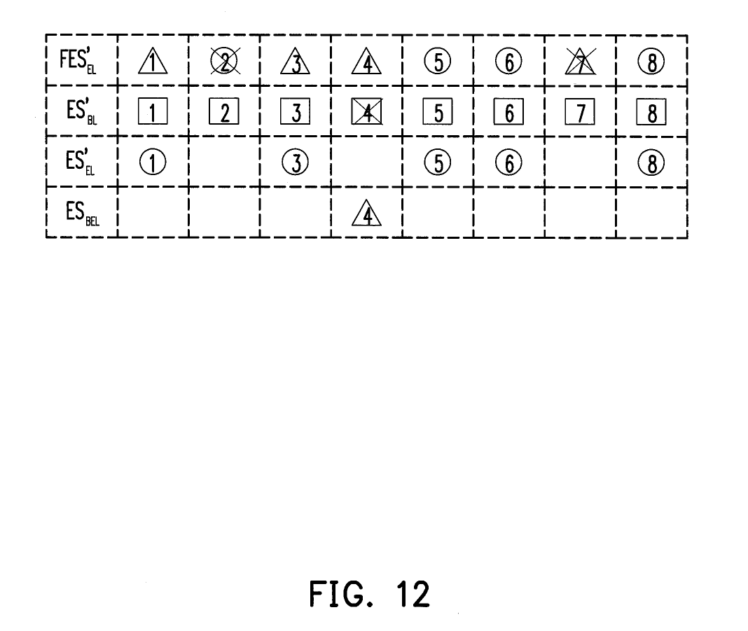

FIG. 12 illustrates an example of a deaggregation operation according to the second exemplary embodiment of the disclosure.

Referring to FIG. 12, in the example illustrated in FIG. 6, after the transmitter transmits the encoding symbols of the base layer encoding symbol set ES_{BL} as encoding symbols of the base layer final encoding symbol set FES_{BL} corresponding to the base layer data to the receiver and transmits the encoding symbols of the enhancement layer final encoding symbol set FES_{EL} corresponding to the enhancement layer data to the receiver, the receiver only receives the 1^{st}, 2^{nd}, 3^{rd}, 5^{th}, 6^{th}, 7^{th}, and 8^{th} encoding symbols (as the base layer encoding symbol set ES′_{BL} in FIG. 12) of the base layer final encoding symbol set FES_{BL} and the 1^{st}, 3^{rd}, 4^{th}, 5^{th}, 6^{th}, and 8th encoding symbols (as the enhancement layer final encoding symbol set FES′_{EL} in FIG. 12) of the enhancement layer final encoding symbol set FES_{EL}.

The symbol deaggregator 804 first adds the non-aggregate encoding symbols (i.e., the 5^{th}, 6^{th}, and 8^{th} encoding symbols of the enhancement layer final encoding symbol set FES′_{EL}) into the enhancement layer encoding symbol set ES′_{EL}. Then, the symbol deaggregator 804 executes an XOR operation according to the 1^{st} and the 3^{rd} encoding symbols of the base layer encoding symbol set ES′_{BL} to restore the 1^{st} and the 3^{rd} encoding symbols of the enhancement layer final encoding symbol set FES′_{EL}. Finally, the non-deaggregatable encoding symbol (i.e., the 4^{th} encoding symbol of the enhancement layer final encoding symbol set FES′_{EL}) is added into the non-deaggregatable encoding symbol set ES_{BEL}.

Referring to FIG. 8 again, the feedback loop FEC decoder 806 reconstructs the base layer source symbol set SS_{BL} and the enhancement layer source symbol set SS_{EL} according to the base layer encoding symbol set ES′_{BL}, the enhancement layer encoding symbol set ES′_{EL}, and the non-deaggregatable encoding symbol set ES_{BEL}.

The feedback loop FEC decoder 806 includes a first FEC decoder 812, a second FEC decoder 814, and a feedback FEC encoder 816.

The first FEC decoder 812 decodes the base layer encoding symbol set ES′_{BL} to output a base layer source symbol set SS′_{BL}.

The second FEC decoder 814 decodes the enhancement layer encoding symbol set ES′_{EL} to output a enhancement layer source symbol set SS′_{EL}.

The feedback FEC encoder 816 encodes the base layer source symbol set SS′_{BL} currently output by the first FEC decoder 812 and the enhancement layer source symbol set SS′_{EL} currently output by the second FEC decoder 814 according to the encoding symbol of the non-deaggregatable encoding symbol set ES_{BEL} to generate a new base layer encoding symbol ES_{BL}^{Extra} not included in the base layer encoding symbol set ES′_{BL} and a new enhancement layer encoding symbol ES_{EL}^{Extra} not included in the enhancement layer encoding symbol set ES′_{EL}.

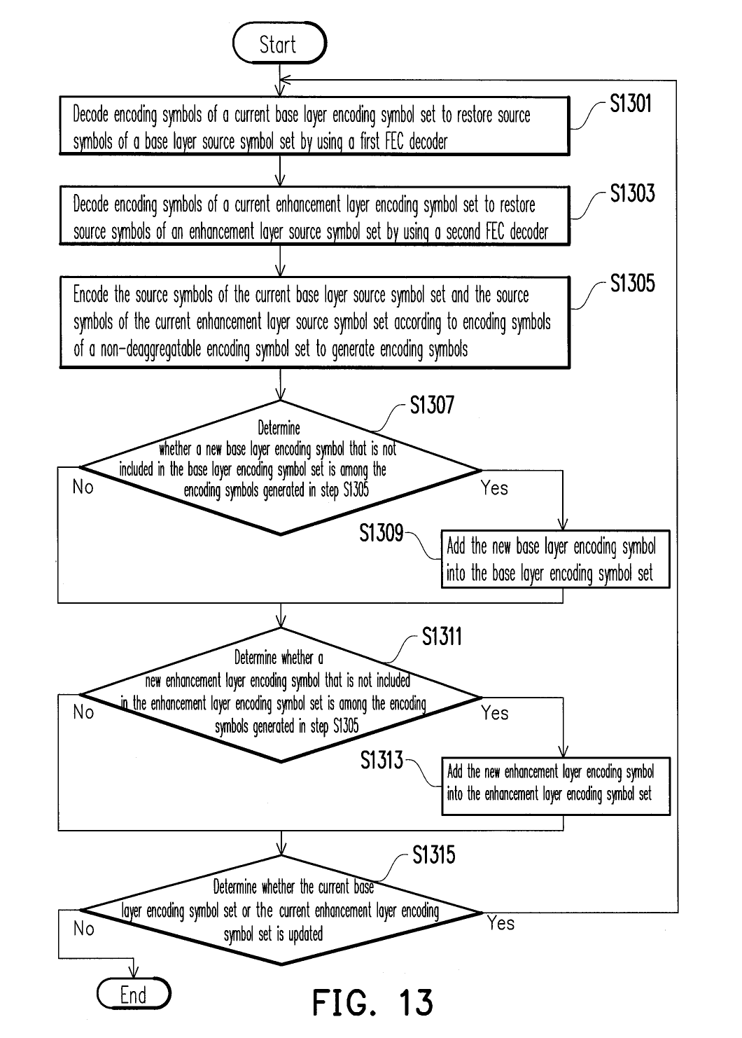

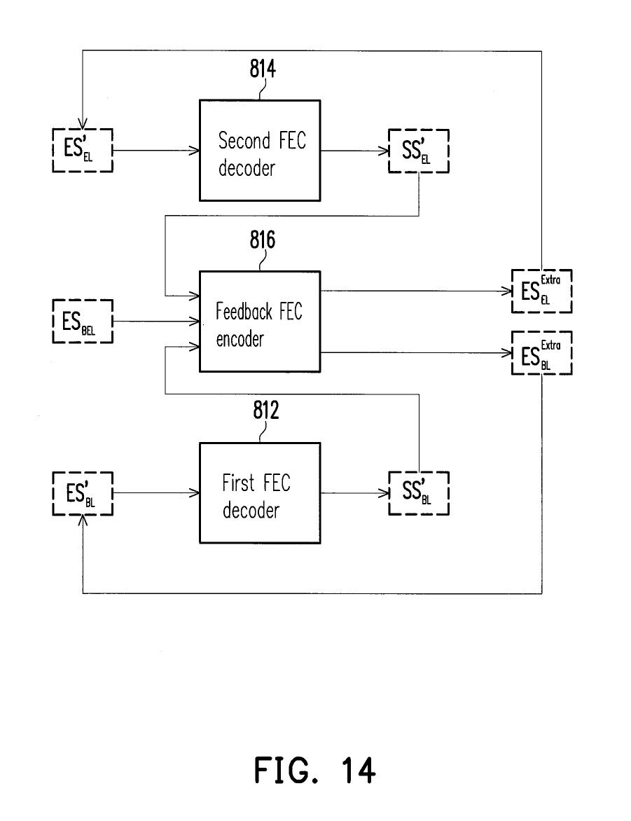

FIG. 13 is a flowchart illustrating the operation of a feedback loop FEC decoder according to the second exemplary embodiment of the disclosure, and FIG. 14 is a diagram illustrating the operation of a feedback loop FEC decoder according to the second exemplary embodiment of the disclosure.

Referring to FIG. 13 and FIG. 14, in step S1301, the first FEC decoder 812 decodes the encoding symbols of the current base layer encoding symbol set ES′_{BL} to restore source symbols of the base layer source symbol set SS′_{BL}, and in step S1303, the second FEC decoder 814 decodes the encoding symbols of the current enhancement layer encoding symbol set ES′_{EL}, to restore source symbols of the enhancement layer source symbol set SS′_{EL}.

In step S1305, the feedback FEC encoder 816 encodes the source symbols of the base layer source symbol set SS′_{BL} currently outputted by the first FEC decoder 812 and the source symbols of the enhancement layer source symbol set SS′_{EL} currently outputted by the second FEC decoder 814 according to the encoding symbols of the non-deaggregatable encoding symbol set ES_{BEL} to generate encoding symbols.

In step S1307, the decoding control module 802 determines whether a new base layer encoding symbol ES_{BL}^{Extra} that is not included in the base layer encoding symbol set ES′_{BL} is among the encoding symbol generated by the feedback FEC encoder 816. If a new base layer encoding symbol ES_{BL}^{Extra} that is not included in the base layer encoding symbol set ES′_{BL} is among the encoding symbols generated by the feedback FEC encoder 816, in step S1309, the decoding control module 802 adds the new base layer encoding symbol ES_{BL}^{Extra} into the base layer encoding symbol set ES′_{BL}.

In step S1311, the decoding control module 802 determines whether a new enhancement layer encoding symbol ES_{EL}^{Extra} that is not included in the enhancement layer encoding symbol set ES′_{EL} is among the encoding symbols generated by the feedback FEC encoder 816. If a new enhancement layer encoding symbol ES_{EL}^{Extra} that is not included in the enhancement layer encoding symbol set ES′_{EL} is among the encoding symbols generated by the feedback FEC encoder 816, in step S1313, the decoding control module 802 adds the new enhancement layer encoding symbol ES_{EL}^{Extra} into the enhancement layer encoding symbol set ES′_{EL}.

To be specific, in step S1305, step S1307, step S1309, and step S1311, existing source symbols are encoded again to obtain the encoding symbols required for deaggregating the non-deaggregatable encoding symbol set ES_{BEL}. For instance, taking an LT encoder as an example, during the encoding process thereof, the LT encoder selects D non-repeated source symbols based on the probability distribution to generate the corresponding encoding symbol. Accordingly, if the source symbols for generating the encoding symbol of the non-deaggregatable encoding symbol set ES_{BEL} can be obtained from the existing source symbols, the encoding symbols required for deaggregating the non-deaggregatable encoding symbol set ES_{BEL} can be generated by re-encoding the source symbols.

In step S1315, the decoding control module 802 determines whether the current base layer encoding symbol set ES′_{BL} or the current enhancement layer encoding symbol set ES′_{EL} is updated. If the current base layer encoding symbol set ES′_{BL} or the current enhancement layer encoding symbol set ES′_{EL} is updated, step S1301, step S1303, step S1305, step S1307, step S1309, step S1311, step S1313, and step S1315 are executed again.

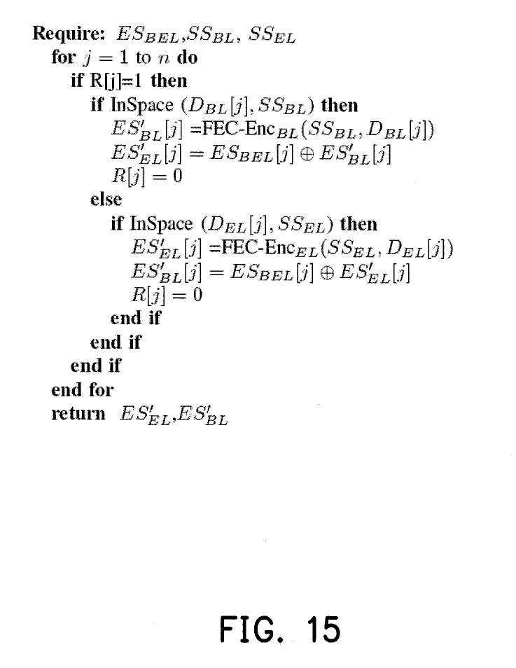

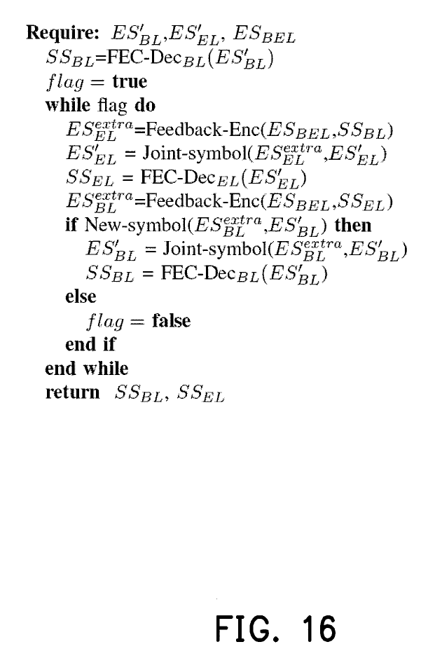

FIG. 15 and FIG. 16 illustrate implementation examples of a feedback FEC encoder and a feedback loop FEC decoder according to the second exemplary embodiment of the disclosure.

In the implementation example illustrated in FIG. 15, D_{BL}[j] represents the encoding vector of the j^{th} base layer encoding symbol, D_{EL}[j] represents the encoding vector of the j^{th} enhancement layer encoding symbol, the InSpace( ) function is used for determining whether the currently restored source symbol set contains the encoding vectors of the corresponding encoding symbol, the FEC-Enc_{BL}( ) function is used for generating the j^{th} base layer encoding symbol according to the encoding vector (D_{BL}[j]) of the j^{th} base layer encoding symbol, and the FEC-Enc_{EL}( ) function is used for generating the j^{th} enhancement layer encoding symbol according to the encoding vector (D_{EL}[j]) of the j^{th} enhancement layer encoding symbol.

In the implementation example illustrated in FIG. 16, the FEC-Dec_{BL}( ) function is used for restoring a base layer source symbol set according to a base layer encoding symbol set, the FEC-Dec_{EL}( ) function is used for restoring an enhancement layer source symbol set according to an enhancement layer encoding symbol set, the Feedback-Enc( ) function is used for generating a new base layer (or enhancement layer) encoding symbol according to the currently restored base layer (or enhancement layer) source symbol set and the non-deaggregatable encoding symbol set, the New-symbol( ) function is used for determining whether the base layer encoding symbol generated by the Feedback-Enc( ) function already exists in the current base layer encoding symbol set, and the Joint-symbol( ) function is used for adding the base layer (or enhancement layer) encoding symbol generated by the Feedback-Enc( ) function into the current base layer (or enhancement layer) encoding symbol set.

It should be understood that the structures illustrated in FIG. 15 and FIG. 16 are only examples of feedback FEC encoder and feedback loop FEC decoder but not intended to limit the scope of the disclosure.

### Third Exemplary Embodiment

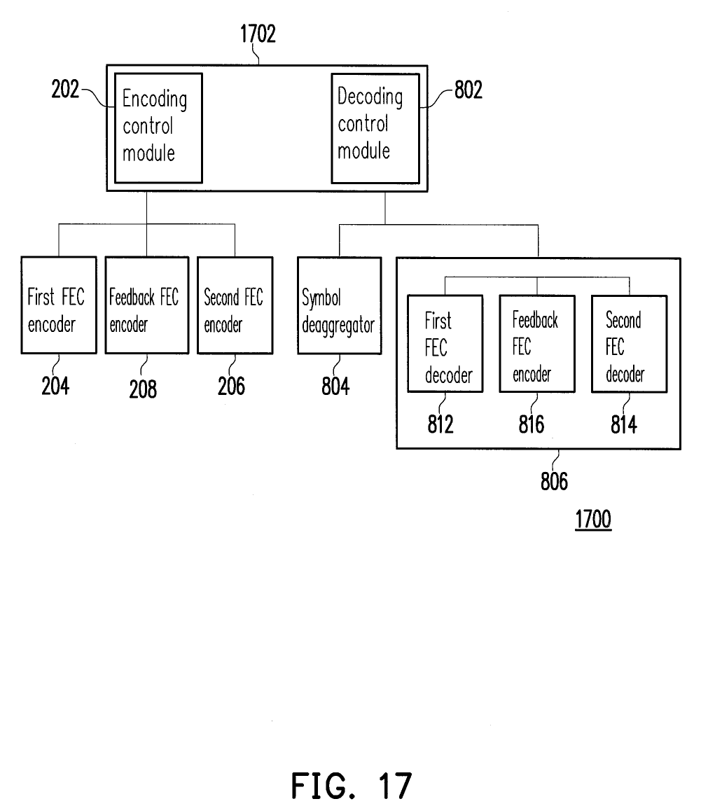

FIG. 17 is a block diagram of a layer-aware FEC encoding/decoding system according to the third exemplary embodiment of the disclosure.

Referring to FIG. 17, the layer-aware FEC encoding/decoding system 1700 includes a controller 1702, the first FEC encoder 204, the second FEC encoder 206, the symbol aggregator 208, the symbol deaggregator 804, and the feedback loop FEC decoder 806.

The controller 1702 includes the encoding control module 202 and the decoding control module 802.

When a device (not shown) disposed with the layer-aware FEC encoding/decoding system 1700 is about to transmit a first information content encoded through an SVC technique, the controller 1702 controls the first FEC encoder 204, the second FEC encoder 206, and the symbol aggregator 208 to encode source symbols of each layer of the first information content through the encoding method described in the foregoing first exemplary embodiment, so as to output final encoding symbols corresponding to each layer. In addition, when the device receives final encoding symbols corresponding to each layer of a second information content, the controller 1702 controls the symbol deaggregator 804 and the feedback loop FEC decoder 806 to decode the received final encoding symbols of each layer through the decoding method described in the foregoing second exemplary embodiment, so as to restore source symbols corresponding to each layer of the second information content.

### Fourth Exemplary Embodiment

Even though the encoding method in the first exemplary embodiment is described with two layers of data (i.e., the base layer data and the enhancement layer data), the disclosure is not limited thereto, and the layer-aware FEC encoding method described above is also applicable to an information content with more layers of data. Below, the encoding method will be described with an information content having three layers of data.

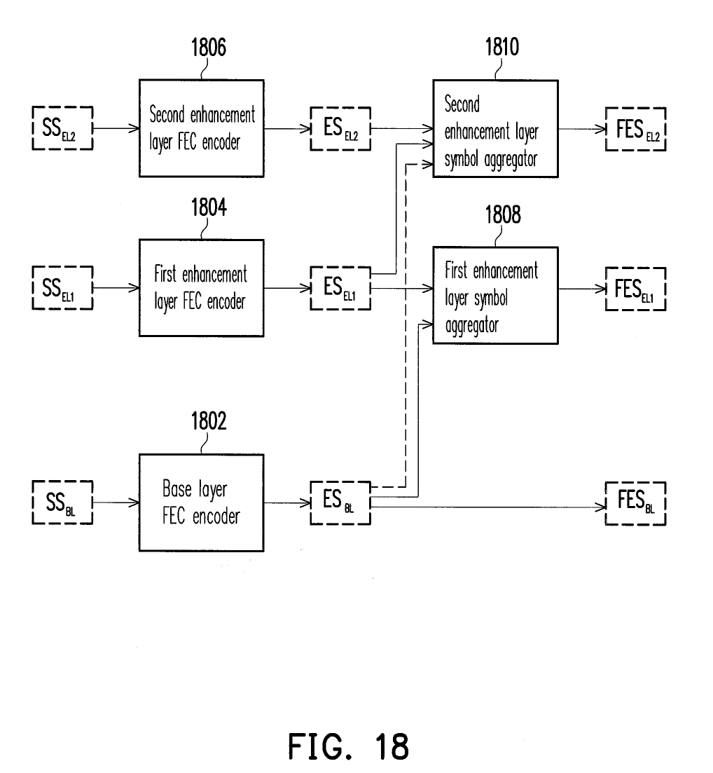

FIG. 18 is a diagram illustrating an encoding operation according to the fourth exemplary embodiment of the disclosure.

Referring to FIG. 18, the information content has a base layer source symbol set SS_{BL}, a first enhancement layer source symbol set SS_{EL1}, and a second enhancement layer source symbol set SS_{EL2}. A base layer FEC encoder 1802, a first enhancement layer FEC encoder 1804, and a second enhancement layer FEC encoder 1806 respectively encode the base layer source symbol set SS_{BL}, the first enhancement layer source symbol set SS_{EL1}, and the second enhancement layer source symbol set SS_{EL2} to generate a base layer encoding symbol set ES_{BL}, a first enhancement layer encoding symbol set ES_{ED}, and a second enhancement layer encoding symbol set ES_{EL2}. Thereafter, the first enhancement layer final encoding symbol set FES_{EL1} is generated through an aggregation operation executed by a first enhancement layer symbol aggregator 1808 according to the base layer encoding symbol set ES_{BL} and the first enhancement layer encoding symbol set ES_{EL1}, and the second enhancement layer final encoding symbol set FES_{EL2} is generated through an aggregation operation executed by a second enhancement layer symbol aggregator 1810 according to the base layer encoding symbol set ES_{BL}, the first enhancement layer encoding symbol set ES_{EL1}, and the second enhancement layer encoding symbol set ES_{EL2}. Herein the aggregation operations executed by the first enhancement layer symbol aggregator 1808 and the second enhancement layer, symbol aggregator 1810 are similar to that in the first exemplary embodiment therefore will not be described herein.

### Fifth Exemplary Embodiment

Even though the decoding method in the second exemplary embodiment is described with two layers of data (i.e., the base layer data and the enhancement layer data), the disclosure is not limited thereto, and the layer-aware FEC decoding method described above is also applicable to an information content with more layers of data. Below, the decoding method will be described with an information content having three layers of data.

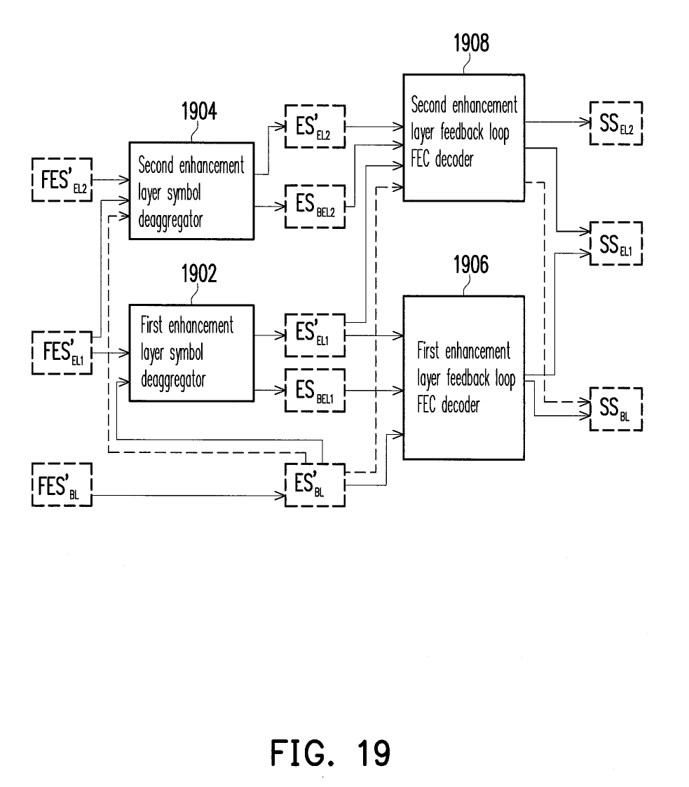

FIG. 19 is a diagram illustrating a decoding operation according to the fifth exemplary embodiment of the disclosure.

Referring to FIG. 19, when a base layer final encoding symbol set FES′_{BL}, a first enhancement layer final encoding symbol set FES′_{ED1}, and a second enhancement layer final encoding symbol set FES′_{EL2} encoded through the encoding method illustrated in FIG. 18 are received, the base layer final encoding symbol set FES′_{BL} is considered as a base layer encoding symbol set ES′_{BL}, and a first enhancement layer symbol deaggregator 1902 executes a deaggregation operation according to the base layer encoding symbol set ES′_{BL} and the first enhancement layer final encoding symbol set FES′_{EL1} to output a first enhancement layer encoding symbol set ES′_{EL1} and a non-deaggregatable encoding symbol set ES_{BEL1}. Besides, a second enhancement layer symbol deaggregator 1904 executes a deaggregation operation according to the base layer final encoding symbol set ES′_{BL}, the first enhancement layer final encoding symbol set FES′_{EL1}, and the second enhancement layer final encoding symbol set FES′_{EL2} to output a second enhancement layer encoding symbol set ES′_{EL2} and a non-deaggregatable encoding symbol set ES_{BEL2}. Herein the deaggregation operations executed by the first enhancement layer symbol deaggregator 1902 and the second enhancement layer symbol deaggregator 1904 are similar to that described in the foregoing second exemplary embodiment therefore will not be described herein.

Thereafter, a first enhancement layer feedback loop FEC decoder 1906 reconstructs a base layer source symbol SS_{BL} and a first enhancement layer source symbol SS_{EL1} through the feedback technique described in the foregoing second exemplary embodiment according to the base layer encoding symbol set ES′_{BL}, the non-deaggregatable encoding symbol set ES_{BEL1}, and the first enhancement layer encoding symbol set ES′_{EL1}. Besides, a second enhancement layer feedback loop FEC decoder 1908 reconstructs a base layer source symbol SS_{BL}, a first enhancement layer source symbol SS_{EL1}, and a second enhancement layer source symbol SS_{EL2} through the feedback technique described in the foregoing second exemplary embodiment according to the base layer encoding symbol set ES′_{BL}, the first enhancement layer encoding symbol set ES_{EL1}, the non-deaggregatable encoding symbol set ES_{BEL2}, and the second enhancement layer encoding symbol set ES′_{EL2}.

### Sixth Exemplary Embodiment

In the first exemplary embodiment, all the base layer encoding symbols selected by the position correspondence function (i.e., those base layer encoding symbols used in the aggregation operation of the symbol aggregator 208) are eventually brought into the base layer final encoding symbol set, so that the receiver may receive the base layer encoding symbols used in the aggregation operation. Thus, in step S1005 in FIG. 10, the symbol deaggregator 804 may generate deaggregated encoding symbols and non-deaggregatable encoding symbols from the aggregate encoding symbols through a deaggregation operation.

However, through the method described above, some aggregate encoding symbols are deaggregated in step S1005 in FIG. 10. Accordingly, these deaggregated encoding symbols can only enhance the data decoding capability on the enhancement layer but not on the base layer. In order to ensure a specific percentage of aggregate encoding symbols are kept for assisting the decoding of the base layer data, more aggregate encoding symbols need to be generated (i.e., a smaller probability value P should be adopted) so that a specific percentage of non-deaggregatable encoding symbols can be obtained after the deaggregation operation for assisting the decoding of the base layer data.

In order to adopt a larger probability value P without sacrificing the protection over the base layer data in the first exemplary embodiment, in the present exemplary embodiment, some adjustments are made to the encoding method in the first exemplary embodiment.

Below, the difference between the sixth exemplary embodiment and the first exemplary embodiment will be explained with reference to FIG. 2, FIG. 3, FIG. 4, and FIG. 7 of the first exemplary embodiment.

First, the base layer final encoding symbol set FES_{BL} is simply a subset of the base layer encoding symbol set ES_{BL}. In other words, not all the base layer encoding symbols generated by the first FEC encoder 204 become base layer final encoding symbols and transmitted to the receiver. To be specific, those base layer encoding symbols selected by the position correspondence function when the symbol aggregator 208 executes the aggregation operation are not brought into the base layer final encoding symbol set FES_{BL}. For example, if the first FEC encoder 204 adopts a rateless FEC coding technique, the first FEC encoder 204 can generate sufficient non-repeated base layer encoding symbols of the base layer encoding symbol set ES_{BL}. This feature makes the actual implementation of the present exemplary embodiment possible. About n₀+n₁(1−P) base layer encoding symbols of the base layer encoding symbol set ES_{BL} are generated in order to keep the coding rate of the base layer, wherein n₁*(1−P) of the base layer encoding symbols of the base layer encoding symbol set ES_{BL} are used for aggregation.

Particularly, in the present exemplary embodiment, in step S407 in FIG. 4, the encoding control module 202 records which base layer encoding symbols are selected by the position correspondence function for executing the aggregation operation. Besides, in step S705 in FIG. 7, the encoding control module 202 further removes the base layer encoding symbols that have been used for executing the aggregation operation from the base layer final encoding symbol set FES_{BL}.

In this case, no symbol could be deaggregated in step S1005, and thus all the aggregate symbols will become non-deagregable symbols. Therefore, the upper and lower limits of the probability value P can be increased in the sixth exemplary embodiment. For example, when it is assumed that the same values as those in the first exemplary embodiment are adopted, the upper and lower limits of the probability value P are revised to (k₁)/(n₁×p₁)≦P≦1−(k₀−n₀×p₀)/n₁×p₁.

### Seventh Exemplary Embodiment

In foregoing first exemplary embodiment, as shown in FIG. 4, N base layer encoding symbols and N enhancement layer encoding symbols are aggregated into N aggregate encoding symbols. In the aggregation operation illustrated in FIG. 6, N=1. To be specific, one base layer encoding symbol and one enhancement layer encoding symbol are aggregated into one aggregate encoding symbol through an XOR operation.

In the present exemplary embodiment, how the aggregation operation is executed when there is N>1 will be explained. Because symbol aggregators and symbol deaggregators come in pairs, herein it is explicitly defined that the symbol aggregators and symbol deaggregators in the present exemplary embodiment should meet following requirements:

1. symbol aggregator: capable of generating N aggregate encoding symbols based on N base layer encoding symbols and N enhancement layer encoding symbols;

2. symbol deaggregator: capable of obtaining all 3N symbols through deaggregation based on any 2N symbols among the foregoing 3N symbols (including the N base layer encoding symbols, the N enhancement layer encoding symbols, and the N aggregate encoding symbols that are generated by aggregating above 2N encoding symbols).

Obviously, the XOR operation in the first exemplary embodiment satisfies foregoing definition with N=1. In addition, any symbol aggregator or symbol deaggregator can be applied in the present exemplary embodiment as long as it satisfies foregoing definition.

The implementations of a symbol aggregator and a symbol deaggregator with N>1 will be described in the present exemplary embodiment by taking RS coding as an example. First, it is assumed that N=2t, wherein t is a positive integer. Namely, N is an even number. The symbol aggregator and the symbol deaggregator are implemented as:

1. symbol aggregator: for executing a systematic RS coding on N base layer encoding symbols and N enhancement layer encoding symbols to generate another N repair symbols of systematic RS coding, and outputting the repair symbols as aggregate encoding symbols.

2. symbol deaggregator: for obtaining all the 3N symbols through deaggregation based on any 2N symbols among the 3N symbols because loss of N symbols among 3N symbols is tolerable according to the definition of systematic RS coding.

The foregoing symbol aggregator and symbol deaggregator can be applied to the situations with N=2t, t=1, 2, . . . . However, other implementations conforming to the foregoing definition of symbol aggregator and symbol deaggregator may also be applied in the present exemplary embodiment.

### Eighth Exemplary Embodiment

The present exemplary embodiment is derived from the sixth exemplary embodiment. In the sixth exemplary embodiment, the upper and lower limits of the possiblity value P are increased. In other words, the number of aggregated enhancement layer encoding symbols decreases. Accordingly, the present exemplary embodiment reflects that the layer-aware FEC encoding/decoding system and method provided by the disclosure can support systematic FEC encoding and decoding.

In the present embodiment, both the first FEC encoder 204 and the first FEC decoder 812 on the base layer adopt systematic FEC encoding and decoding algorithms. Namely, the former k₀, encoding symbols of the base layer encoding symbol set ES_{BL} are all the source symbols of the base layer source symbol set SS_{BL}, and the later n₀−k₀ encoding symbols of the base layer encoding symbol set ES_{BL} are repair symbols. Besides, both the second FEC encoder 206 and the second FEC decoder 814 on the enhancement layer adopt systematic FEC encoding and decoding algorithms. Namely, the former k₁ encoding symbols of the enhancement layer encoding symbol set ES_{EL} are all the source symbols of the enhancement layer source symbol set SS_{EL}, and the later n₁−k₁ encoding symbols of the enhancement layer encoding symbol set ES_{EL} are repair symbols.

To make the layer-aware FEC encoding and decoding system and method provided by the disclosure to support systematic FEC encoding and decoding, the enhancement layer final encoding symbol set FES_{EL} also has to keep the systematic FEC encoding and decoding features. Namely, the former k₁ encoding symbols of the enhancement layer encoding symbol set ES_{EL} are not used in the operation of the symbol aggregator 208, and only the later n₁−k₁ encoding symbols of the enhancement layer encoding symbol set ES_{EL} are possible to be used in the operation of the symbol aggregator. To be specific, in step S405 in FIG. 4, the second encoding symbol group contains only the later n₁−k₁ encoding symbols (i.e., the aforementioned repair symbols) of the enhancement layer encoding symbol set ES_{EL}.

The systematic FEC encoding/decoding technique described above requires the repair symbols on the enhancement layer to take a percentage greater than or equal to 1−P (i.e., the percentage of the desired aggregate encoding symbols). When this condition is met, the base layer and enhancement layer FEC encoding modules (i.e., the first FEC encoder 204 and the first FEC decoder 812 of the base layer and the second FEC encoder 206 and the second FEC decoder 814 of the enhancement layer) in the sixth exemplary embodiment and the first exemplary embodiment can adopt the systematic FEC encoding and decoding algorithms. However, compared to that in the first exemplary embodiment, the value of 1−P in the sixth exemplary embodiment is much smaller. Accordingly, foregoing condition is more likely to be met, and the method in the present embodiment is more likely to be adopted.

In summary, in an exemplary embodiment of the disclosure, the encoding of data on an upper layer is related to data on a lower layer, and accordingly the data on the lower layer can be reconstructed according to encoded data on the upper layer. In addition, in the present exemplary embodiment, the data coding rate on each layer is the same as the data coding rate on each layer in a FEC infrastructure with independent data coding on each layer. Namely, the encoding/decoding complexity of each layer does not increase along with the level of the layer. Moreover, data on each layer can be encoded/decoded by using different FEC encoders/decoders according to the actual requirement. In particular, existing FEC encoding/decoding modules can be applied to the present exemplary embodiment without any modification.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A layer-aware Forward Error Correction (FEC) encoding method, for encoding an information content, wherein the information content has a plurality of layer source symbol sets, the layer source symbol sets at least have a first layer source symbol set and a second layer source symbol set, and the first layer source symbol set and the second layer source symbol set respectively have a plurality of source symbols, the layer-aware FEC encoding method comprising:
encoding the source symbols of the first layer source symbol set by using a first FEC encoder to generate a plurality of encoding symbols of a first layer encoding symbol set, and encoding the source symbols of the second layer source symbol set by using a second FEC encoder to generate a plurality of encoding symbols of a second layer encoding symbol set;
serving the encoding symbols of the first layer encoding symbol set as a plurality of encoding symbols of a first layer final encoding symbol set corresponding to the first layer source symbol set; and
executing an aggregation operation on the encoding symbols of the second layer encoding symbol set according to the encoding symbols of the first layer encoding symbol set to generate a plurality of encoding symbols of a second layer final encoding symbol set corresponding to the second layer source symbol set.

2. The layer-aware FEC encoding method according to claim 1, wherein the step of executing the aggregation operation on the encoding symbols of the second layer encoding symbol set according to the encoding symbols of the first layer encoding symbol set to generate the encoding symbols of the second layer final encoding symbol set corresponding to the second layer source symbol set comprises:
dividing the encoding symbols of the second layer encoding symbol set into a first encoding symbol group and a second encoding symbol group;
executing the aggregation operation on the encoding symbols in the second encoding symbol group according to the encoding symbols of the first layer encoding symbol set to generate a plurality of aggregate encoding symbols of an aggregate encoding symbol set; and
replacing a portion of the encoding symbols of the second layer encoding symbol set with the aggregate encoding symbols of the aggregate encoding symbol set to generate the encoding symbols of the second layer final encoding symbol set.

3. The layer-aware FEC encoding method according to claim 2, wherein the step of dividing the encoding symbols of the second layer encoding symbol set into the first encoding symbol group and the second encoding symbol group comprises:
dividing the encoding symbols of the second layer encoding symbol set into the first encoding symbol group and the second encoding symbol group according to a probability value.

4. The layer-aware FEC encoding method according to claim 2, wherein the step of executing the aggregation operation on the encoding symbols of the second encoding symbol group according to the encoding symbols of the first layer encoding symbol set to generate the aggregate encoding symbols of the aggregate encoding symbol set comprises:
selecting N encoding symbols from the second encoding symbol group;
selecting N encoding symbols from the first layer encoding symbol set by using a position correspondence function;
aggregating the N encoding symbols selected in step a and the N encoding symbols selected in step b to generate N aggregate encoding symbols;
adding the N aggregate encoding symbols generated in step c into the aggregate encoding symbol set;
removing the N encoding symbols selected from the second encoding symbol group in step a, and determining whether the number of the remaining encoding symbols in the second encoding symbol group is smaller than N; and
when the number of the remaining encoding symbols in the second encoding symbol group is smaller than N, adding the remaining encoding symbols into the second layer final encoding symbol set, and when the number of the remaining encoding symbol in the second encoding symbol group is not smaller than N, executing the above steps again,
wherein N is a natural number.

5. The layer-aware FEC encoding method according to claim 4, wherein step c comprises:
respectively executing an XOR operation on the N encoding symbols selected in step a and the N encoding symbols selected in step b to generate the N aggregate encoding symbols.

6. The layer-aware FEC encoding method according to claim 4 further comprising:
recording the N encoding symbols selected from the first layer encoding symbol set by using the position correspondence function in step b; and
removing the N encoding symbols selected from the first layer encoding symbol set by using the position correspondence function in step b from the first layer final encoding symbol set.

7. The layer-aware FEC encoding method according to claim 2, wherein the encoding symbols of the second layer encoding symbol set comprise a plurality of repair symbols,
wherein the step of dividing the encoding symbols of the second layer encoding symbol set into the first encoding symbol group and the second encoding symbol group comprises:
grouping the repair symbols among the encoding symbols of the second layer encoding symbol set into the second encoding symbol group.

8. A layer-aware FEC decoding method, for decoding a plurality of final layer encoding symbol sets corresponding to an information content, wherein the final layer encoding symbol sets at least have a first layer final encoding symbol set and a second layer final encoding symbol set, and the first layer final encoding symbol set and the second layer final encoding symbol set respectively have a plurality of encoding symbols, the layer-aware FEC decoding method comprising:
serving the encoding symbols of the first layer final encoding symbol set as a plurality of encoding symbols of a first layer encoding symbol set;
executing a deaggregation operation on the encoding symbols of the second layer final encoding symbol set according to the encoding symbols of the first layer encoding symbol set to generate a second layer encoding symbol set and a non-deaggregatable encoding symbol set; and
generating a first layer source symbol set and a second layer source symbol set according to the first layer encoding symbol set, the second layer encoding symbol set, and the non-deaggregatable encoding symbol set by using a feedback loop FEC decoder.

9. The layer-aware FEC decoding method according to claim 8, wherein the step of executing the deaggregation operation on the encoding symbols of the second layer final encoding symbol set according to the encoding symbols of the first layer encoding symbol set to generate the second layer encoding symbol set and the non-deaggregatable encoding symbol set comprises:
identifying a plurality of non-aggregate encoding symbols and a plurality of aggregate encoding symbols among the encoding symbols of the second layer final encoding symbol set;
executing the deaggregation operation on the aggregate encoding symbols according to the encoding symbols of the first layer encoding symbol set to generate a plurality of deaggregated encoding symbols and at least one non-deaggregatable encoding symbol;
generating the second layer encoding symbol set with the at least one non-aggregate encoding symbol and the deaggregated encoding symbols; and
generating the non-deaggregatable encoding symbol set with the at least one non-deaggregatable encoding symbol.

10. The layer-aware FEC decoding method according to claim 9, wherein the step of executing the deaggregation operation on the aggregate encoding symbols according to the encoding symbols of the first layer encoding symbol set to generate the deaggregated encoding symbols and at least one non-deaggregatable encoding symbol comprises:
executing an XOR operation on the aggregate encoding symbols according to the encoding symbols of the first layer encoding symbol set to generate the deaggregated encoding symbols and at least one non-deaggregatable encoding symbol.

11. The layer-aware FEC decoding method according to claim 8, wherein the step of generating the first layer source symbol set and the second layer source symbol set according to the first layer encoding symbol set, the second layer encoding symbol set, and the non-deaggregatable encoding symbol set by using the feedback loop FEC decoder comprises:
decoding the encoding symbols of the first layer encoding symbol set by using a first FEC decoder to generate a plurality of source symbols of a current first layer source symbol set;
decoding the encoding symbols of the second layer encoding symbol set by using a second FEC decoder to generate a plurality of source symbols of a current second layer source symbol set;
encoding the source symbols of the current first layer source symbol set and the source symbols of the current second layer source symbol set according to the non-deaggregatable encoding symbol set by using a feedback FEC encoder, and determining whether to generate a new first layer encoding symbol or a new second layer encoding symbol according to the encoding symbols of the first layer encoding symbol set and the encoding symbols of the second layer encoding symbol set; and
when the new first layer encoding symbol or the new second layer encoding symbol is generated, adding the new first layer encoding symbol into the first layer encoding symbol set or adding the new second layer encoding symbol into the second layer encoding symbol set, and executing the above steps again.

12. A layer-aware FEC encoding apparatus, for encoding an information content, wherein the information content has a plurality of layer source symbol sets, the layer source symbol sets at least have a first layer source symbol set and a second layer source symbol set, and the first layer source symbol set and the second layer source symbol set respectively have a plurality of source symbols, the layer-aware FEC encoding apparatus comprising:
an encoding control module, configured to receive the layer source symbol sets;
a first FEC encoder, configured to encode the source symbols of the first layer source symbol set to generate a plurality of encoding symbols of a first layer encoding symbol set, wherein the encoding control module serves the encoding symbols of the first layer encoding symbol set generated by the first FEC encoder as a plurality of encoding symbols of a first layer final encoding symbol set corresponding to the first layer source symbol set;
a second FEC encoder, configured to encode the source symbol of the second layer source symbol set to generate a plurality of encoding symbols of a second layer encoding symbol set; and
a symbol aggregator, configured to execute an aggregation operation on the encoding symbols of the second layer encoding symbol set according to the encoding symbols of the first layer encoding symbol set to generate a plurality of encoding symbols of a second layer final encoding symbol set corresponding to the second layer source symbol set,
wherein the encoding control module further outputs the encoding symbols of the first layer final encoding symbol set and the encoding symbols of the second layer final encoding symbol set.

13. The layer-aware FEC encoding apparatus according to claim 12,
wherein the symbol aggregator divides the encoding symbols of the second layer encoding symbol set into a first encoding symbol group and a second encoding symbol group, executes the aggregation operation on the encoding symbols in the second encoding symbol group according to the encoding symbols of the first layer encoding symbol set to generate a plurality of aggregate encoding symbols of an aggregate encoding symbol set, and replaces a portion of the encoding symbols of the second layer encoding symbol set with the aggregate encoding symbols of the aggregate encoding symbol set to generate the encoding symbols of the second layer final encoding symbol set.

14. The layer-aware FEC encoding apparatus according to claim 13,
wherein the symbol aggregator divides the encoding symbols of the second layer encoding symbol set into the first encoding symbol group and the second encoding symbol group according to a probability value.

15. The layer-aware FEC encoding apparatus according to claim 13,
wherein the symbol aggregator executes following steps to generate the aggregate encoding symbol:
selecting N encoding symbols from the second encoding symbol group;
selecting N encoding symbols from the first layer encoding symbol set by using a position correspondence function;
aggregating the N encoding symbols selected in step a and the N encoding symbols selected in step b to generate N aggregate encoding symbol;
adding the N aggregate encoding symbols generated in step c into the aggregate encoding symbol set;
removing the N encoding symbols selected from the second encoding symbol group in step a, and determining whether the number of the remaining encoding symbols in the second encoding symbol group is smaller than N; and
when the number of the remaining encoding symbols in the second encoding symbol group is smaller than N, adding the remaining encoding symbols into the second layer final encoding symbol set, and when the number of the remaining encoding symbols in the second encoding symbol group is not smaller than N, executing the above steps again,
wherein N is a natural number.

16. The layer-aware FEC encoding apparatus according to claim 15,
wherein the symbol aggregator respectively executes an XOR operation on the N encoding symbols selected in step a and the N encoding symbols selected in step b to generate the N aggregate encoding symbol.

17. The layer-aware FEC encoding apparatus according to claim 15,
wherein the encoding control module further records the N encoding symbols selected from the first layer encoding symbol set by using the position correspondence function in step b,
wherein the encoding control module further removes the N encoding symbols selected from the first layer encoding symbol set by using the position correspondence function in step b from the first layer final encoding symbol set.

18. The layer-aware FEC encoding apparatus according to claim 13, wherein the encoding symbols of the second layer encoding symbol set have a plurality of repair symbols,
wherein the symbol aggregator groups the repair symbols among the encoding symbols of the second layer encoding symbol set into the second encoding symbol group.

19. A layer-aware FEC decoding apparatus, for decoding a plurality of final layer encoding symbol sets corresponding to an information content, wherein the final layer encoding symbol sets at least have a first layer final encoding symbol set and a second layer final encoding symbol set, and the first layer final encoding symbol set and the second layer final encoding symbol set respectively have a plurality of encoding symbols, the layer-aware FEC decoding apparatus comprising:
a decoding control module, configured to serve the encoding symbols of the first layer final encoding symbol set as a plurality of encoding symbols of a first layer encoding symbol set;
a symbol deaggregator, configured to execute a deaggregation operation on the encoding symbols of the second layer final encoding symbol set according to the encoding symbols of the first layer encoding symbol set to generate a second layer encoding symbol set and a non-deaggregatable encoding symbol set; and
a feedback loop FEC decoder, configured to generate a first layer source symbol set and a second layer source symbol set according to the first layer encoding symbol set, the second layer encoding symbol set, and the non-deaggregatable encoding symbol set,
wherein the decoding control module outputs the first layer source symbol set and the second layer source symbol set.

20. The layer-aware FEC decoding apparatus according to claim 19,
wherein the symbol deaggregator identifies a plurality of non-aggregate encoding symbols and a plurality of aggregate encoding symbols among the encoding symbol of the second layer final encoding symbol set, executes the deaggregation operation on the aggregate encoding symbols according to the encoding symbol of the first layer encoding symbol set to generate a plurality of deaggregated encoding symbols and at least one non-deaggregatable encoding symbol, generates the second layer encoding symbol set with the least one non-aggregate encoding symbol and the deaggregated encoding symbols, and generates the non-deaggregatable encoding symbol set with the at least one non-deaggregatable encoding symbol.

21. The layer-aware FEC decoding apparatus according to claim 20, wherein the symbol deaggregator executes an XOR operation on the aggregate encoding symbols according to the encoding symbols of the first layer encoding symbol set to generate the deaggregated encoding symbols and the at least one non-deaggregatable encoding symbol.

22. The layer-aware FEC decoding apparatus according to claim 19, wherein the feedback loop FEC decoder comprises:
a first FEC decoder, configured to decode the encoding symbols of the first layer encoding symbol set to generate a plurality of source symbols of a current first layer source symbol set;
a second FEC decoder, configured to decode the encoding symbols of the second layer encoding symbol set to generate a plurality of source symbols of a current second layer source symbol set; and
a feedback FEC encoder, configured to encode the source symbols of the current first layer source symbol set and the source symbols of the current second layer source symbol set according to the non-deaggregatable encoding symbol set and generating a new first layer encoding symbol or a new second layer encoding symbol,
wherein the decoding control module adds the new first layer encoding symbol into the first layer encoding symbol set or adds the new second layer encoding symbol into the second layer encoding symbol set.

23. A layer-aware FEC encoding/decoding system, comprising:
a controller, comprising:
an encoding control module, configured to receive a plurality of layer source symbol sets of a first information content, wherein the layer source symbol sets of the first information content at least have a first layer source symbol set and a second layer source symbol set of the first information content, and the first layer source symbol set and the second layer source symbol set of the first information content respectively have a plurality of source symbols; and
a decoding control module, configured to receive a plurality of final layer encoding symbol sets corresponding to a second information content, wherein the final layer encoding symbol sets of the second information content at least have a first layer final encoding symbol set and a second layer final encoding symbol set of the second information content, the first layer final encoding symbol set and the second layer final encoding symbol set of the second information content respectively have a plurality of encoding symbols, and the decoding control module serves the first layer final encoding symbol set of the second information content as a first layer encoding symbol set of the second information content;
a first FEC encoder, configured to encode the source symbols of the first layer source symbol set of the first information content to generate a plurality of encoding symbols of a first layer encoding symbol set of the first information content, wherein the encoding control module serves the encoding symbols of the first layer encoding symbol set of the first information content as a plurality of encoding symbols of a first layer final encoding symbol set of the first information content;
a second FEC encoder, configured to encode the source symbols of the second layer source symbol set of the first information content to output a plurality of encoding symbols of a second layer encoding symbol set of the first information content;
a symbol aggregator, configured to execute an aggregation operation on the encoding symbols of the second layer encoding symbol set of the first information content according to the encoding symbols of the first layer encoding symbol set of the first information content to generate a plurality of encoding symbols of a second layer final encoding symbol set of the first information content;
a symbol deaggregator, configured to execute a deaggregation operation on the encoding symbols of the second layer final encoding symbol set of the second information content according to the encoding symbols of the first layer encoding symbol set of the second information content to generate a second layer encoding symbol set and a non-deaggregatable encoding symbol set of the second information content; and
a feedback loop FEC decoder, configured to generate a first layer source symbol set and a second layer source symbol set of the second information content according to the first layer encoding symbol set, the second layer encoding symbol set, and the non-deaggregatable encoding symbol set of the second information content,
wherein the controller outputs the first layer final encoding symbol set and the second layer final encoding symbol set of the first information content and outputs the first layer source symbol set and the second layer source symbol set of the second information content.
